(19) United States
(12) Patent Application Publication
(10) Pub. No.: US 2026/0089942 A1
(43) Pub. Date: Mar. 26, 2026

(54) BONDED ASSEMBLIES AND METHODS FOR FORMING THE SAME USING POLYMER-BASED HYBRID BONDING

(71) Applicant: Sandisk Technologies, Inc., Milpitas, CA (US)

(72) Inventors: Mitsuteru MUSHIGA, Kuwana (JP); Akio NISHIDA, Yokkaichi (JP); Masaaki HIGASHITANI, Cupertino, CA (US)

(21) Appl. No.: 18/891,177

(22) Filed: Sep. 20, 2024

(51) Int. Cl. H10B 43/27; G11C 16/04; H01L 25/065; H10B 43/10; H10B 43/35; H10B 80/00

(52) U.S. Cl. CPC H10B 43/27; G11C 16/0483; H10B 43/10; H10B 43/35; H10B 80/00; H10W 90/00; H10W 90/722

(57) ABSTRACT

A bonded assembly includes a first memory die including a first alternating stack of first insulating layers and first electrically conductive layers, first memory stack structures vertically extending through the first alternating stack, first metal interconnect structures embedded within first memory-die inorganic dielectric layers, and first memory-die copper bonding pads embedded within a first polymer dielectric layer, and a second memory die including a second alternating stack of second insulating layers and second electrically conductive layers, second memory stack structures vertically extending through the second alternating stack, second metal interconnect structures embedded within second memory-die inorganic dielectric layers, and second memory-die copper bonding pads embedded within a second polymer dielectric layer.

### FIELD

The present disclosure relates generally to the field of semiconductor devices, and particularly to bonded assemblies and methods for forming the same using polymer-based hybrid bonding.

### BACKGROUND

Flash memory devices include NAND and NOR memory devices. Such memory devices may be formed by sequentially depositing memory device layers over a driver circuit located on a silicon wafer.

### SUMMARY

According to an aspect of the present disclosure, a semiconductor structure comprising a bonded assembly comprises: a first memory die including a first alternating stack of first insulating layers and first electrically conductive layers, first memory stack structures vertically extending through the first alternating stack, first metal interconnect structures embedded within first memory-die inorganic dielectric layers, and first memory-die copper bonding pads contacting a respective one of the first metal interconnect structures and embedded within a first polymer dielectric layer; and a second memory die including a second alternating stack of second insulating layers and second electrically conductive layers, second memory stack structures vertically extending through the second alternating stack, second metal interconnect structures embedded within second memory-die inorganic dielectric layers, and second memory-die copper bonding pads contacting a respective one of the second metal interconnect structures and embedded within a second polymer dielectric layer.

According to another aspect of the present disclosure, a method of forming a semiconductor structure comprising a bonded assembly is provided. The method comprises: providing a first memory die including a first alternating stack of first insulating layers and first electrically conductive layers, first memory stack structures vertically extending through the first alternating stack, first metal interconnect structures embedded within first memory-die inorganic dielectric layers, and first memory-die copper bonding pads contacting a respective one of the first metal interconnect structures and embedded within a first polymer dielectric layer; providing a second memory die including a second alternating stack of second insulating layers and second electrically conductive layers, second memory stack structures vertically extending through the second alternating stack, second metal interconnect structures embedded within second memory-die inorganic dielectric layers, and second memory-die copper bonding pads contacting a respective one of the second metal interconnect structures and embedded within a second polymer dielectric layer; and providing the first memory die and the second memory die into a bonded assembly.

### BRIEF DESCRIPTION OF THE DRAWINGS

FIG. 1 is a schematic vertical cross-sectional view of a region of an exemplary in-process memory die after formation of a backside dielectric layer, in-process source-level material layers, an alternating stack of insulating layers and sacrificial material layers having stepped surfaces, and a retro-stepped dielectric material portion over a carrier substrate according to an embodiment of the present disclosure.

FIG. 2A is a schematic vertical cross-sectional view of a region of the exemplary in-process memory die after forming memory openings according to an embodiment of the present disclosure. FIG. 2B is a top-down view of the exemplary in-process memory die of FIG. 2A. The vertical plane A-A′ is the cut plane of the vertical cross-sectional view of FIG. 2A. FIG. 2C is a top-down view of the exemplary in-process memory die at the processing steps of FIGS. 2A and 2B.

FIGS. 3A-3D are sequential vertical cross-sectional views of a memory opening during formation of a memory opening fill structure according to an embodiments of the present disclosure.

FIG. 4 is a vertical cross-sectional view of a region of the exemplary in-process memory die after formation of memory opening fill structures according to an embodiment of the present disclosure.

FIG. 5A is a vertical cross-sectional view of a region of the exemplary in-process memory die after formation of a contact-level dielectric layer, a patterned hard mask layer, lateral isolation trenches, and discrete through-stack openings according to an embodiment of the present disclosure. FIG. 5B is a top-down view of a region of the exemplary in-process memory die of FIG. 5A. The vertical plane A-A′ is the cut plane of the vertical cross-sectional view of FIG. 5A. FIG. 5C is a top-down view of the exemplary in-process memory die including the exemplary in-process memory die at the processing steps of FIGS. 5A and 5B.

FIG. 6 is a vertical cross-sectional view of a region of the exemplary in-process memory die after vertical extension of the discrete through-stack openings according to an embodiment of the present disclosure.

FIG. 7 is a vertical cross-sectional view of a region of the exemplary in-process memory die after formation of sacrificial lateral isolation trench fill structures and sacrificial through-stack opening fill structures according to an embodiment of the present disclosure.

FIG. 8 is a vertical cross-sectional view of a region of the exemplary in-process memory die after removal of the sacrificial lateral isolation trench fill structures according to an embodiment of the present disclosure.

FIG. 9 is a vertical cross-sectional view of a region of the exemplary in-process memory die after formation of a source cavity according to an embodiment of the present disclosure.

FIG. 10 is a vertical cross-sectional view of a region of the exemplary in-process memory die after formation of a source contact layer and dielectric capping liners according to an embodiment of the present disclosure.

FIG. 11 is a vertical cross-sectional view of a region of the exemplary in-process memory die after formation of laterally-extending cavities according to an embodiment of the present disclosure.

FIG. 12 is a vertical cross-sectional view of a region of the exemplary in-process memory die after formation of electrically conductive layers according to an embodiment of the present disclosure.

FIG. 13 is a vertical cross-sectional view of a region of the exemplary in-process memory die after formation of lateral isolation trench fill structures and contact via structures according to an embodiment of the present disclosure.

FIG. 14 is a vertical cross-sectional view of a region of the exemplary in-process memory die after removal of the sacrificial through-stack opening fill structures according to an embodiment of the present disclosure.

FIG. 15 is a vertical cross-sectional view of a region of the exemplary in-process memory die after formation of tubular dielectric spacers and through-stack via structures according to an embodiment of the present disclosure.

FIG. 16 is a vertical cross-sectional view of a region of the exemplary in-process memory die after formation of layer contact via structures, drain contact via structures, and peripheral connection via structures according to an embodiment of the present disclosure.

FIG. 17 is a vertical cross-sectional view of a region of the exemplary in-process memory die after formation of a memory die according to an embodiment of the present disclosure.

FIG. 18 is a vertical cross-sectional view of a region of an exemplary memory-controller die after formation of controller semiconductor devices and controller lower-level dielectric material layers according to an embodiment of the present disclosure.

FIG. 19 is a vertical cross-sectional view of a region of the exemplary memory-controller die after formation of through-substrate via structures according to an embodiment of the present disclosure.

FIG. 20 is a vertical cross-sectional view of a region of the exemplary memory-controller die after formation of a memory-controller die according to an embodiment of the present disclosure.

FIG. 21 is a vertical cross-sectional view of a region of a first exemplary bonded assembly of a memory die and a memory-controller die according to an embodiment of the present disclosure.

FIG. 22 is a vertical cross-sectional view of a region of the first exemplary bonded assembly after optional removal of a carrier substrate from the memory die according to an embodiment of the present disclosure.

FIG. 23 is a vertical cross-sectional view of a region of the first exemplary bonded assembly after formation of backside via openings according to an embodiment of the present disclosure.

FIG. 24 is a vertical cross-sectional view of a region of the first exemplary bonded assembly after formation of proximal metal interconnect structures according to an embodiment of the present disclosure.

FIG. 25 is a vertical cross-sectional view of a region of the first exemplary bonded assembly after formation of a memory-die inorganic dielectric layer and a patterned polymer dielectric layer according to an embodiment of the present disclosure.

FIG. 26A is a vertical cross-sectional view of a region of the first exemplary bonded assembly after formation of memory-die copper bonding pads according to an embodiment of the present disclosure. FIG. 26B is a top-down view of the first exemplary bonded assembly of FIG. 26A. FIGS. 26C and 26D are vertical cross-sectional views of a region of the first exemplary bonded assembly after formation of memory-die copper bonding pads according to an alternative embodiment of the present disclosure.

FIG. 27 is a vertical cross-sectional view of a second exemplary bonded assembly of two memory dies and two memory-controller dies according to an embodiment of the present disclosure.

FIG. 28 is a vertical cross-sectional view of the second exemplary bonded assembly after thinning the backside of a first controller-side semiconductor substrate of the first memory-controller die according to an embodiment of the present disclosure.

FIG. 29 is a vertical cross-sectional view of the second exemplary bonded assembly after formation of a controller-die backside dielectric layer according to an embodiment of the present disclosure.

FIG. 30 is a vertical cross-sectional view of the second exemplary bonded assembly after formation of first controller-die backside bonding structures according to an embodiment of the present disclosure.

FIG. 31 is a vertical cross-sectional view of the second exemplary bonded assembly after formation of second controller-die backside bonding structures according to an embodiment of the present disclosure.

FIG. 32A is a vertical cross-sectional view of a first exemplary structure including multiple instances of the second exemplary bonded assembly according to an embodiment of the present disclosure. FIG. 32B is a vertical cross-sectional view of a second exemplary structure including multiple instances of the second exemplary bonded assembly according to an embodiment of the present disclosure.

FIG. 33 is a vertical cross-sectional view of a third exemplary bonded assembly after formation according to an embodiment of the present disclosure.

FIG. 34A is a vertical cross-sectional view of a third exemplary structure including multiple instances of the third exemplary bonded assembly according to an embodiment of the present disclosure. FIG. 34B is a vertical cross-sectional view of a fourth exemplary structure including multiple instances of the third exemplary bonded assembly according to an embodiment of the present disclosure.

### DETAILED DESCRIPTION

As discussed above, the embodiments of the present disclosure are directed to bonded assemblies and methods for forming the same using polymer-based hybrid bonding, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which may be the smallest unit that can be erased in a single erase operation. Alternatively, subblocks may be the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

One approach to achieving higher memory densities involves vertically stacking memory dies using through-silicon vias (TSVs) and metal bonding pads to form interconnects between the memory dies. Wafer-to-wafer (W2W) and die-to-wafer (D2W) bonding techniques may be used to form bonded assemblies of stacked memory dies.

Wafer-level die sorting (D/S) may be performed before bonding, and this process may result in mechanical damage to the bonding pads. Probe marks left by the testing process can significantly affect the quality of the bonding surface, leading to bonding failures. Such probe marks can disrupt the electrical connection between stacked dies, resulting in reduced performance and reliability. In addition, using micro-bumps to bond one bonded assembly to another bonded assembly uses larger than desired bonding pads. A reduction in the size of bonding pads is desirable to increase the memory device density.

Embodiments of the present disclosure utilizing polymer-based hybrid bonding, to enhance structural and electrical integrity of bonded assemblies that incorporate through-silicon vias (TSVs) and copper bonding pads. These embodiments reduce or eliminate bonding surface degradation caused by probe mark defects during wafer-level die sorting (D/S) and increase device density by permitting the use of smaller bonding pads.

The use of polymer dielectric layers, such as polyimide, in the hybrid bonding process offers several advantages. First, the polymer dielectric layer serves as a protective layer for the copper bonding pads during wafer-level die sorting. This helps to mitigate the effects of probe marks that can compromise the bonding surface. By embedding the copper bonding pads in the polymer dielectric, the structural integrity of the copper-to-copper bonding interface is maintained, which enhances the reliability of the final bonded assembly. Additionally, the polymer layer allows for chemical mechanical planarization (CMP), ensuring a smooth and even bonding surface that improves alignment and contact between stacked dies.

Another advantage of polymer-based hybrid bonding is its ability to accommodate smaller TSV pitches relative to micro-bump bonding, which improves the memory device density.

The polymer materials, particularly polyimide, also provide thermal and mechanical stability, which is advantageous in high-performance applications, such as 3D NAND flash memory and high-bandwidth memory (HBM). The ability of the polymer dielectric to withstand thermal cycling and mechanical stresses improves the longevity and reliability of the bonded assembly.

In embodiments of the present disclosure, a bonded assembly is formed from a first memory die and a second memory die, each of which includes an alternating stack of insulating and electrically conductive layers, and memory stack structures that extend vertically through these alternating layers. Both the first memory die and the second memory die contain copper bonding pads, which are embedded within polymer dielectric layers, such as polyimide. These copper bonding pads are bonded to one another by copper-to-copper bonding, establishing electrical connection between the two memory dies. Additionally, the polymer dielectric layers are bonded to one another through polymer-to-polymer bonding, which provides mechanical stability to the bonded assembly. The various embodiments of the present disclosure are now described with reference to accompanying drawings.

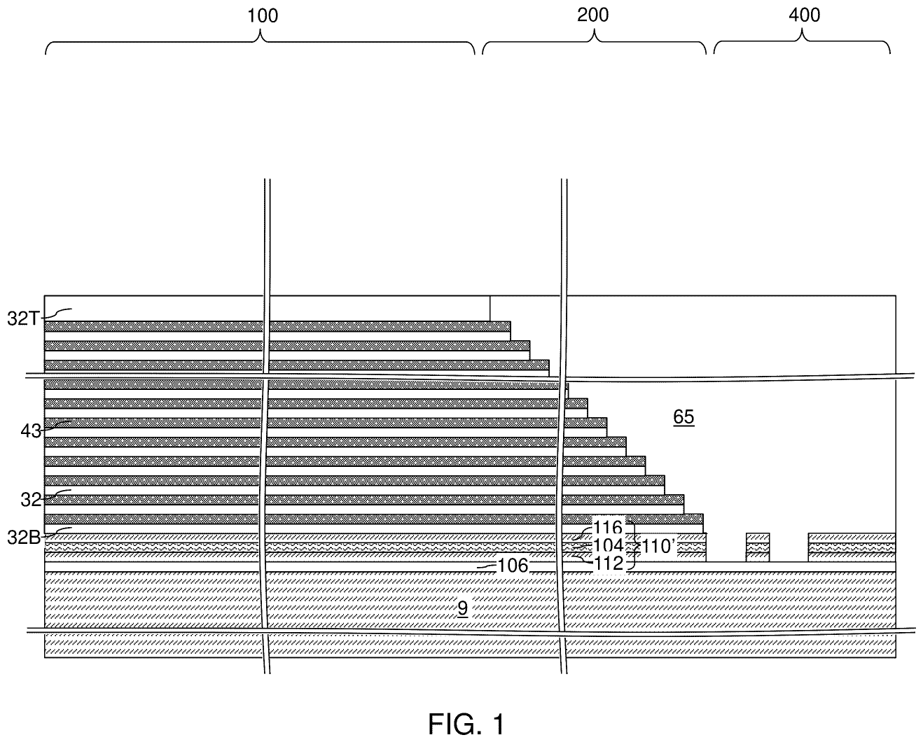

Referring to FIG. 1, an exemplary in-process memory die according to an embodiment of the present disclosure is illustrated. The exemplary in-process memory die comprises a carrier substrate 9, which may be a semiconductor substrate, a dielectric substrate, or a conductive substrate. For example, the carrier substrate 9 may comprise a commercially available silicon wafer. Alternatively, the carrier substrate 9 may comprise any material that may be removed selectively to the materials of a first memory-die proximal inorganic dielectric layer 106 and a retro-stepped dielectric material portion 65 to be subsequently formed.

A dielectric material layer can be formed on a top surface of the carrier substrate 9. The dielectric material layer can be subsequently employed as a stopping material layer for a process that removes the carrier substrate 9, and is herein referred to as a first memory-die proximal inorganic dielectric layer 106, or as a stopper dielectric layer. The first memory-die proximal inorganic dielectric layer 106 comprises and/or consists essentially of an inorganic dielectric material, such as undoped silicate glass (i.e., silicon oxide), a doped silicate glass, or silicon nitride. If a polishing process such as a chemical mechanical polishing process is employed to subsequently remove the carrier substrate 9, the first memory-die proximal inorganic dielectric layer 106 may be subsequently employed as a polishing stopper material layer. If an etch process such as a wet etch process is employed to subsequently remove the carrier substrate 9, the first memory-die proximal inorganic dielectric layer 106 may be subsequently employed as an etch stop material layer. In one embodiment, the first memory-die proximal inorganic dielectric layer 106 comprises a dielectric material such as undoped silicate glass, a doped silicate glass, or silicon nitride. The thickness of the first memory-die proximal inorganic dielectric layer 106 may be in a range from 50 nm to 600 nm, such as from 100 nm to 300 nm, although lesser and greater thicknesses may also be employed.

In-process source-level material layers 110′ can be formed over the first memory-die proximal inorganic dielectric layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner (not shown), a source-level sacrificial layer 104, an optional upper sacrificial liner (not shown), and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selectively to the lower sacrificial liner (or selectively to the lower source-level semiconductor layer 112) and the upper sacrificial liner (or selectively to the upper source-level semiconductor layer 116). In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used. The lower sacrificial liner (if present) and the upper sacrificial liner (if present) include materials that may function as an etch stop material during removal of the source-level sacrificial layer 104. For example, the lower sacrificial liner and the upper sacrificial liner may include silicon oxide, silicon nitride, and/or a dielectric metal oxide. In one embodiment, each of the lower sacrificial liner and the upper sacrificial liner may include a silicon oxide layer having a thickness in a range from 2 nm to 30 nm, although lesser and greater thicknesses may also be used.

An alternating stack of first material layers and second material layers can be formed over the in-process source-level material layers 110′. In an alternative embodiment, the in-process source-level material layers 110′ and the first memory-die proximal inorganic dielectric layer 106 may be omitted, and the alternating stack is formed directly on a surface of the carrier substrate 9. In the alternating stack, the first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layers 110′. The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about twice the thickness of other insulating layers 32.

Stepped surfaces are formed in a contact region 200. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layers 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is employed for the retro-stepped dielectric material portion 65, the silicon oxide of the retro-stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

The exemplary in-process memory die comprises a memory array region 100 in which each layer within the alternating stack (32, 42) is present and in which a three-dimensional array of memory elements is to be subsequently formed, the contact region 200 which contains the stepped surfaces of the alternating stack (32, 42) and in which layer contact via structures contacting word lines are to be subsequently formed, and a peripheral region 400 in which the layers within the alternating stack (32, 42) are absent. The peripheral region 400 may comprise a kerf region through which the memory dies will be diced and an edge seal region. Openings may be formed through the in-process source-level material layers 110′ in the peripheral region 400 for formation of edge seal structures.

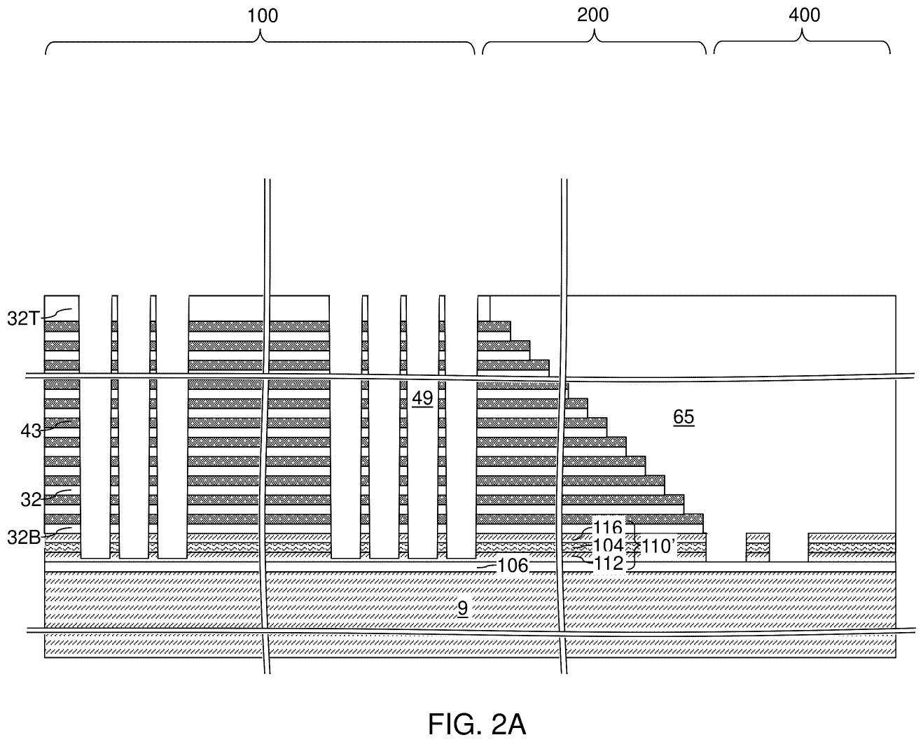

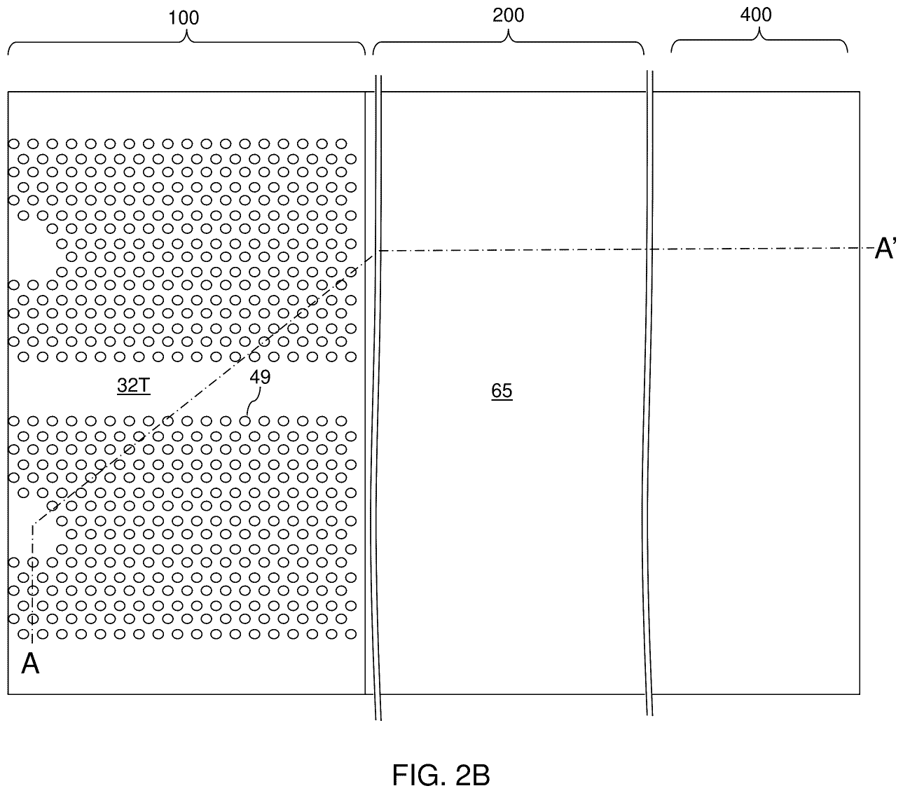

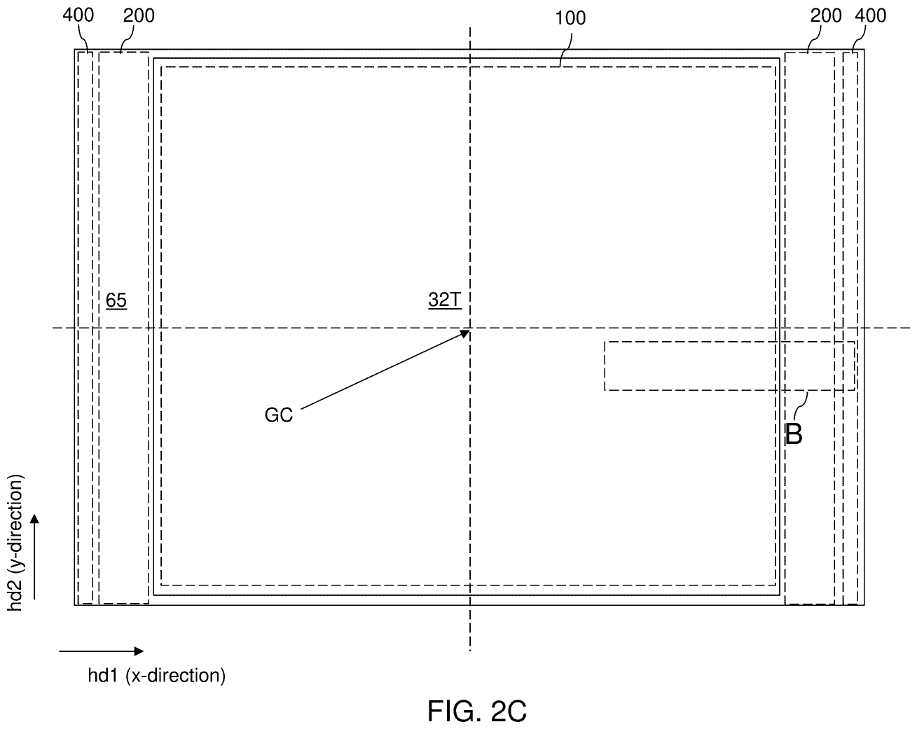

Referring to FIG. 2A-2C, various views of the exemplary in-process memory die are illustrated after formation of memory openings 49. FIG. 2C is a top-down view of the exemplary in-process memory die that illustrates an entire area of an in-process memory die. FIG. 2B is a top-down view of region B of the top-down view of the exemplary in-process memory die shown in FIG. 2C. FIG. 2A is a vertical cross-sectional view of the exemplary in-process memory die along the vertical plane A-A′ of FIG. 2B. The in-process memory die may have a rectangular shape in a plan view, such as the top-down view of FIG. 2C. The geometrical center GC of the in-process memory die is also illustrated in FIG. 2C. As used herein, a geometrical center of an element refers to a center of gravity of a hypothetical object occupying the same volume as the element and having a uniform density throughout.

Specifically, an etch mask layer (not shown) can be formed over the alternating stack (32, 42) and the retro-stepped dielectric material portion 65, and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100 and support openings (not illustrated) that are formed in the contact region 200. Each of the memory openings 49 and the support openings can vertically extend through the alternating stack (32, 42) and into the in-process source-level material layers 110′ In one embodiment, bottom surfaces of the memory openings 49 and the support openings may be formed within the lower source-level semiconductor layer 112 or at an interface between the lower source-level semiconductor layer and the first memory-die proximal inorganic dielectric layer 106.

The support openings may have a diameter in a range from 60 nm to 400 nm, such as from 120 nm to 300 nm, although lesser and greater thicknesses may be employed. The memory openings 49 may have a diameter in a range from 60 nm to 400 nm, such as from 120 nm to 300 nm, although lesser and greater thicknesses may be employed.

In one embodiment, the memory array region 100 may be laterally spaced apart from the contact region 200 along a first horizontal direction hd1. The memory openings 49 may comprise rows of memory openings 49 that are arranged along the first horizontal direction hd1 and laterally spaced apart along a second horizontal direction hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2.

Sacrificial memory opening fill structures (not shown) can be formed in the memory openings 49. The sacrificial memory opening fill structures may comprise a carbon-based material (such as amorphous carbon or diamond-like carbon), a semiconductor material (such as amorphous silicon or polysilicon), a dielectric fill material (such as borosilicate glass or organosilicate glass), or a polymer material. A dielectric fill material can be deposited in the support openings to form support pillar structures (not shown). The sacrificial memory opening fill structures can be subsequently removed to form cavities in the memory openings 49.

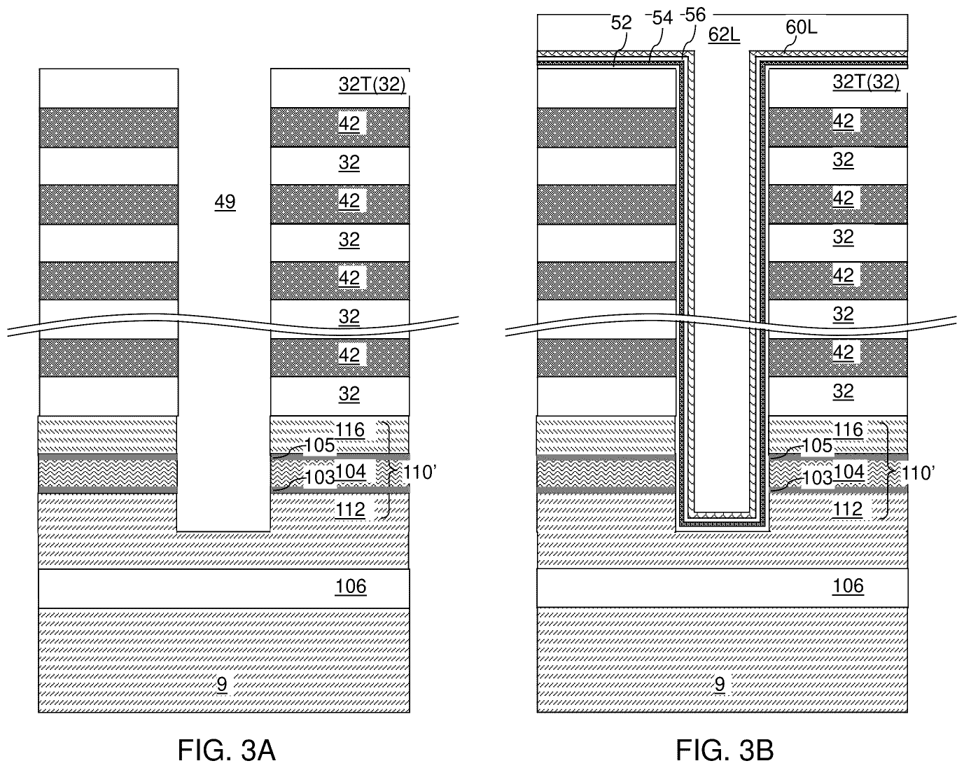

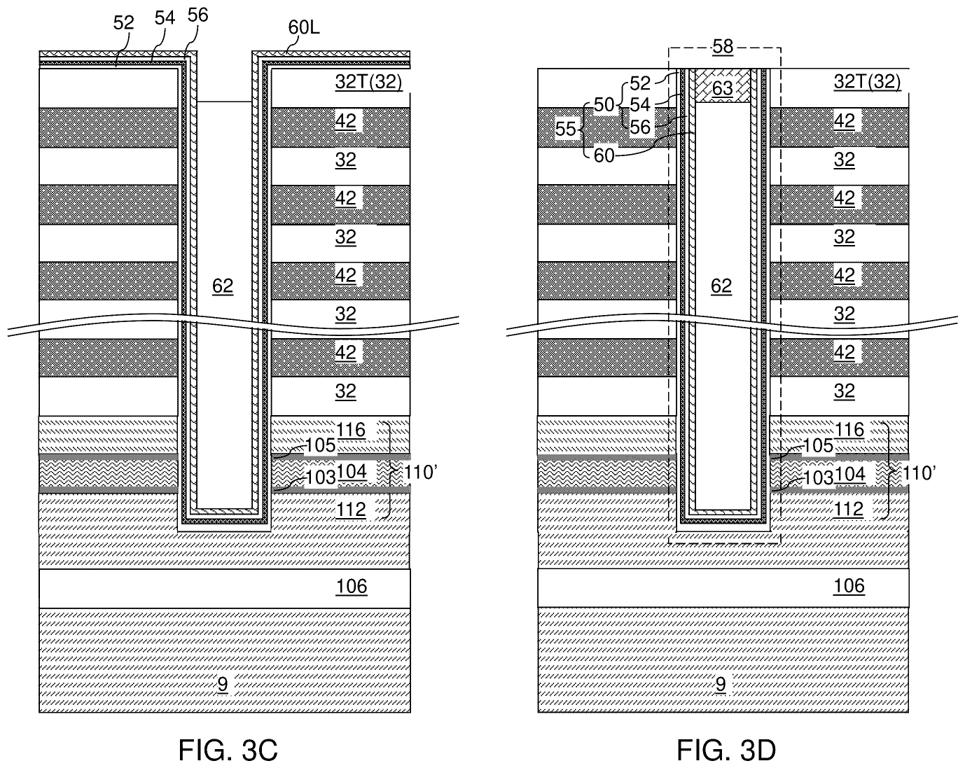

FIGS. 3A-3D are sequential vertical cross-sectional views of a memory opening 49 during formation of a NAND string (e.g., a dummy NAND string or a data storage NAND string) which is referred to below as a “memory opening fill structure” 58 according to an embodiment of the present disclosure.

Referring to FIG. 3A, a memory opening 49 is illustrated after the processing steps of FIGS. 2A-2C.

Referring to FIG. 3B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride). In case the memory material layer 54 comprises a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 3C, the dielectric core layer 62L can be vertically recessed such that each remaining portion of the dielectric core layer 62L has a top surface at, or about, the horizontal plane including the bottom surface of the topmost insulating layer 32T. Each remaining portion of the dielectric core layer 62L constitutes a dielectric core 62.

Referring to FIG. 3D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42.

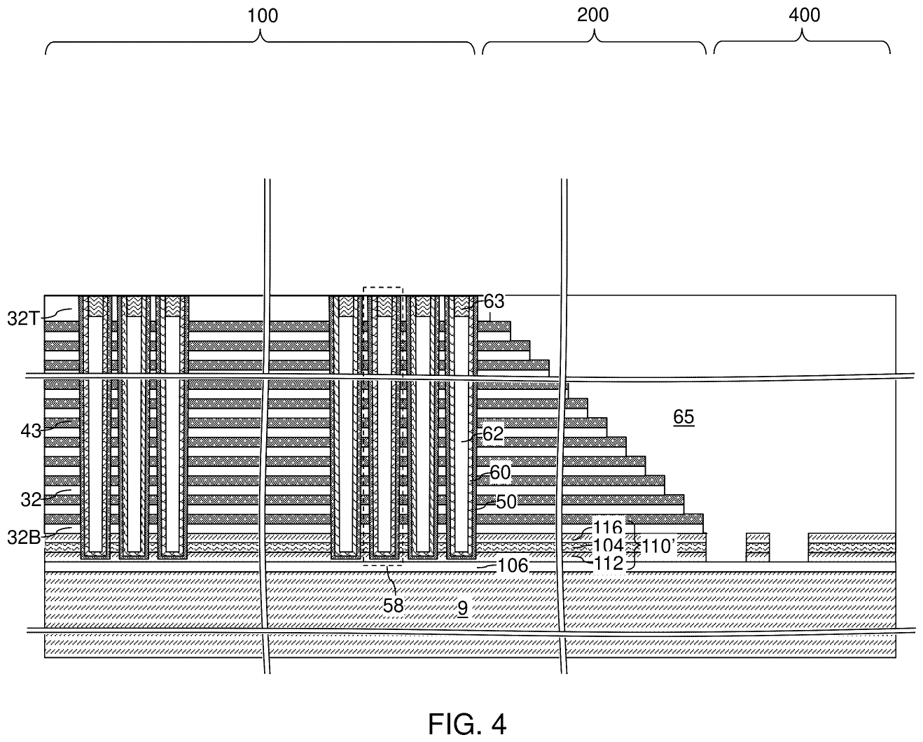

Referring to FIG. 4, the exemplary in-process memory die is illustrated after formation of memory opening fill structures 58 within the memory openings 49. Each of the memory opening fill structures 58 may comprise a memory stack structure 55, which comprises a memory film 50 and a vertical semiconductor channel 60. A combination of an alternating stack (32, 42) of insulating layers 32 and sacrificial material layers 42, memory openings 49 vertically extending through the alternating stack (32, 42), and memory opening fill structures 58 located in the memory openings 49 can be formed. Each of the memory opening fill structures 58 comprises a respective vertical stack of memory elements, such as portions of a memory material layer 54 located at levels of the sacrificial material layers 42.

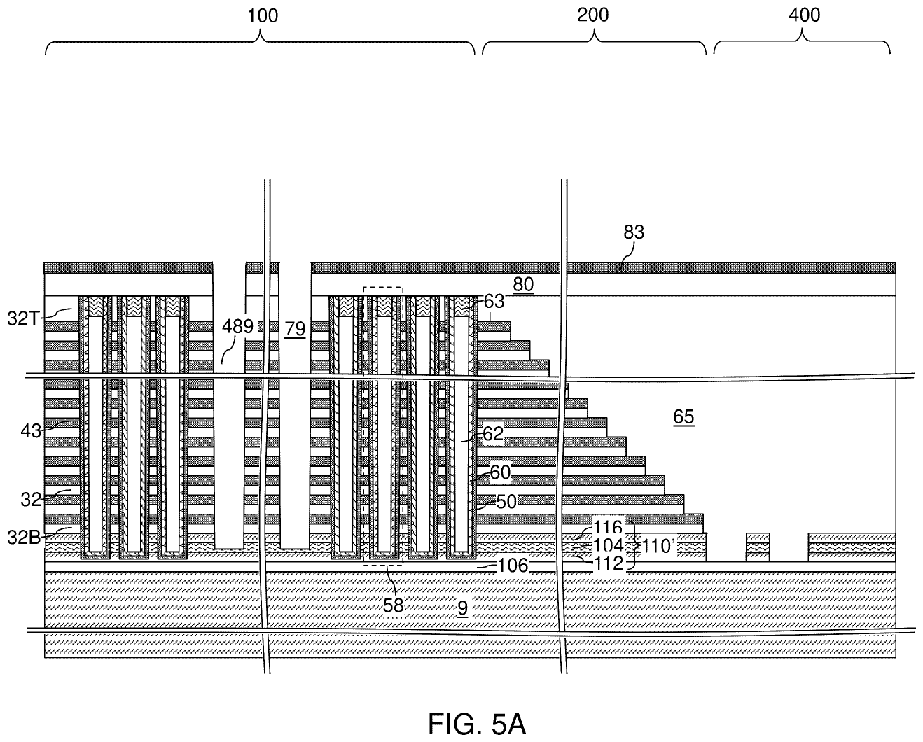

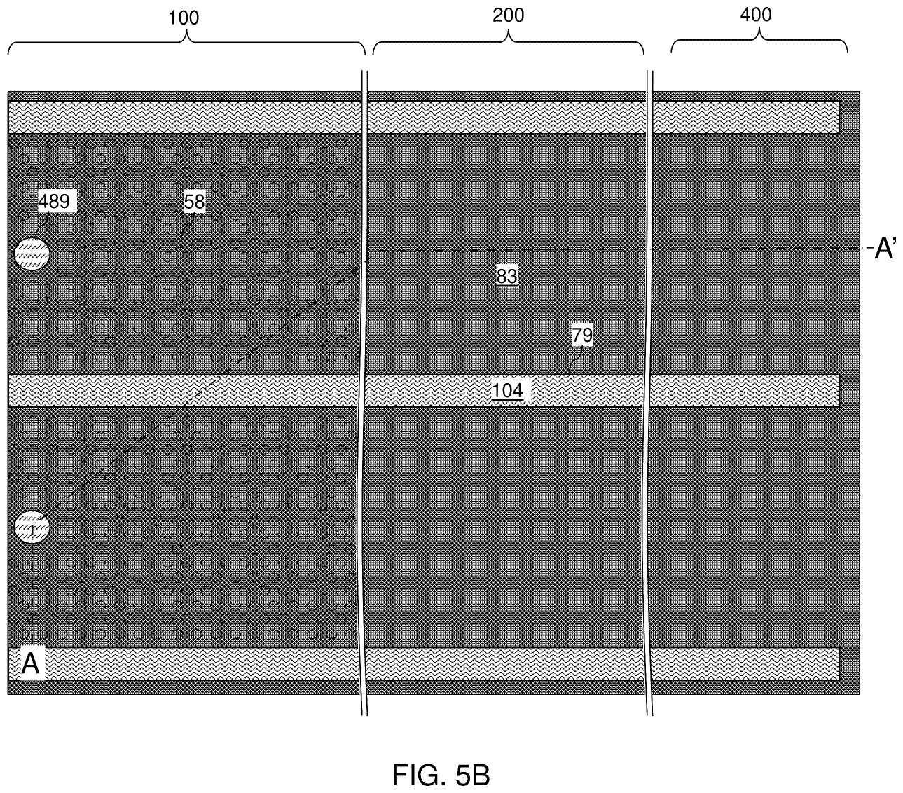

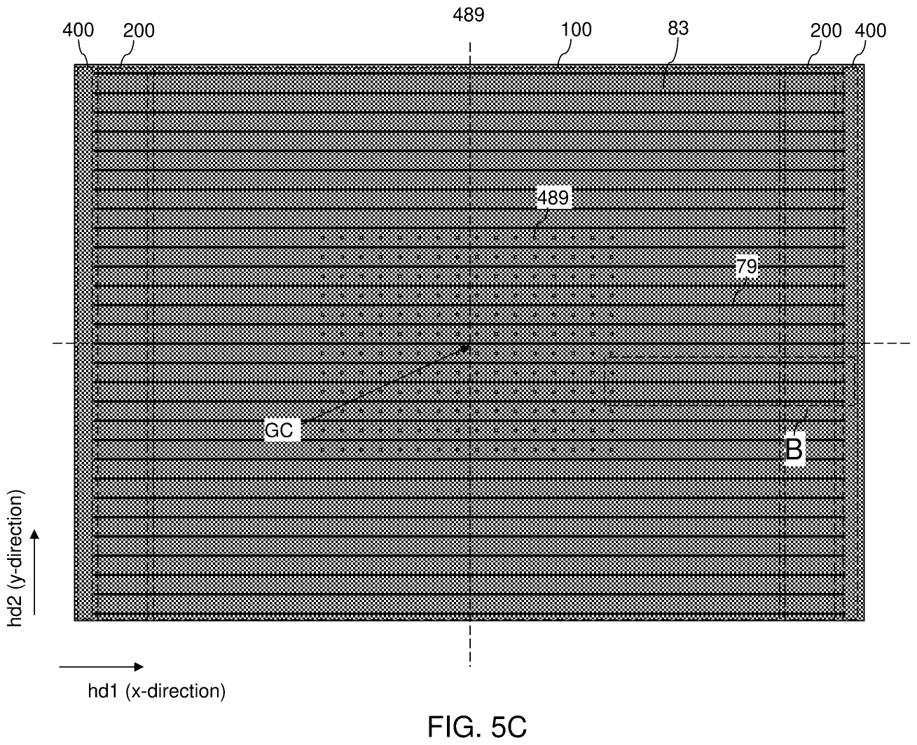

Referring to FIGS. 5A-5C , various views of the exemplary are illustrated after formation of a contact-level dielectric layer 80, a patterned hard mask layer 83, lateral isolation trenches 79, and through-stack openings 489. FIG. 5C is a top-down view of the exemplary in-process memory die that illustrates an entire area of an in-process memory die. FIG. 5B is a top-down view of region B of the top-down view of the exemplary in-process memory die shown in FIG. 5C. FIG. 5A is a vertical cross-sectional view of the exemplary in-process memory die along the vertical plane A-A′ of FIG. 5B.

Specifically, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A hard mask material can be deposited over the contact-level dielectric layer 80, and can be patterned to form a patterned hard mask layer 83. The hard mask layer 83 may comprise any suitable hard mask material, such as titanium nitride, polysilicon, silicon nitride, etc. The pattern of the openings in the patterned hard mask layer 83 may comprise elongated openings that laterally extend along the first horizontal direction hd1 between neighboring clusters (e.g., memory blocks) of memory opening fill structures 58 through the memory array region 100 and a pair of contact regions 200, and discrete openings having circular horizontal cross-sectional shapes.

An anisotropic etch process can be performed to transfer the pattern of the openings in the patterned hard mask layer 83 through the contact-level dielectric layer 80, the alternating stack (32, 42), the retro-stepped dielectric material portion 65, and upper layers of the in-process source-level material layers 110′. Lateral isolation trenches 79 laterally extending along the first horizontal direction hd1 can be formed through the alternating stack (32, 42), the retro-stepped dielectric material portion 65, the contact-level dielectric layer 80, and upper layers of the in-process source-level material layers 110′ underneath the elongated openings in the patterned hard mask layer 83. Through-stack openings 489 can be formed through the alternating stack (32, 42), the retro-stepped dielectric material portion 65, the contact-level dielectric layer 80, and upper layers of the in-process source-level material layers 110′ underneath the discrete openings in the patterned hard mask layer 83. In one embodiment, bottom surfaces of the lateral isolation trenches 79 and the through-stack openings 489 may comprise surface segments of the source-level sacrificial layer 104. In one embodiment, the through-stack openings 489 may be arranged as a two-dimensional periodic array. In one embodiment, the through-stack openings 489 may be formed in a center region of the in-process memory die in a plan view. In one embodiment, peripheral regions of the in-process memory die may be free of any through-stack openings 489.

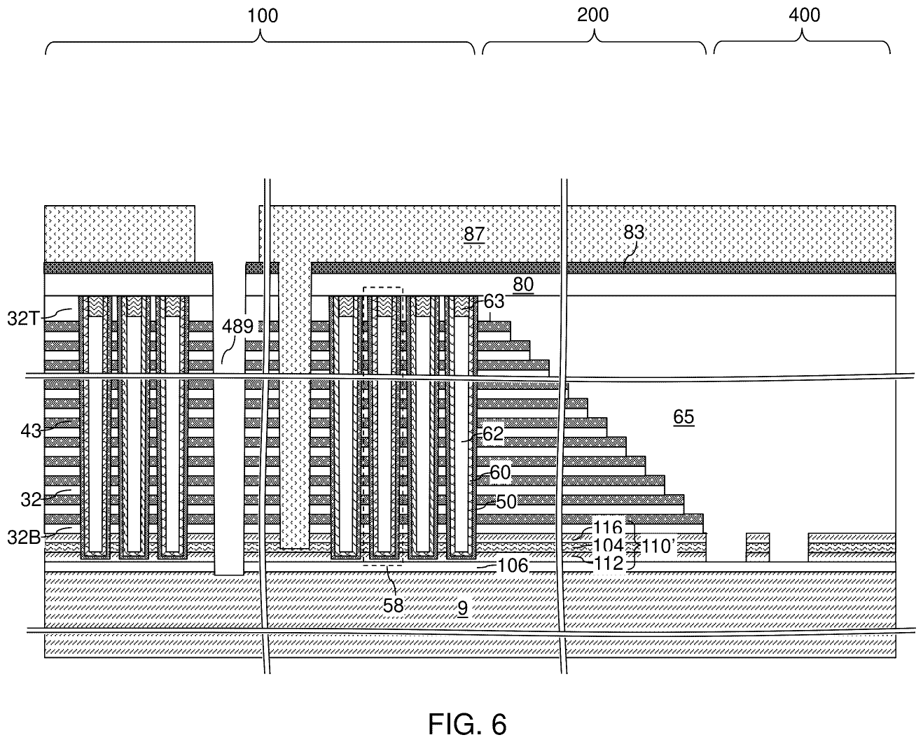

Referring to FIG. 6, a photoresist layer 87 can be applied over the exemplary in-process memory die, and can be lithographically patterned to form openings around the through-stack openings 489. The photoresist layer 87 can cover all areas of the lateral isolation trenches 79. An anisotropic etch process can be performed to vertically extend the through-stack openings 489 through the in-process source-level material layers 110′ and the first memory-die proximal inorganic dielectric layer 106 and optionally into an upper portion of the carrier substrate 9. The photoresist layer 87 can be subsequently removed, for example, by ashing. The patterned hard mask layer 83 can be removed selectively to the contact-level dielectric layer, for example, by performing a wet etch process.

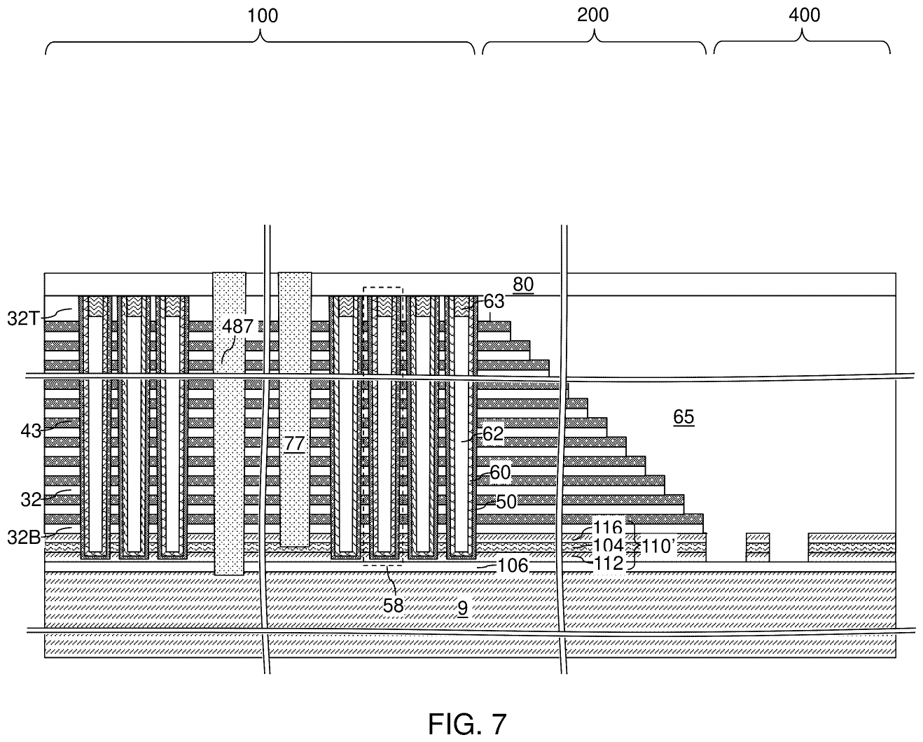

Referring to FIG. 7, a sacrificial fill material can be deposited in the lateral isolation trenches 79 and the through-stack openings 489. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material. Excess portions of the sacrificial fill material can be removed from above the horizontal plane including the top surface of the contact-level dielectric layer 80. Remaining portions of the sacrificial fill material filling the lateral isolation trenches 79 constitute sacrificial lateral isolation trench fill structures 77. Remaining portions of the sacrificial fill material filling the through-stack openings 489 constitute sacrificial through-stack opening fill structures 487.

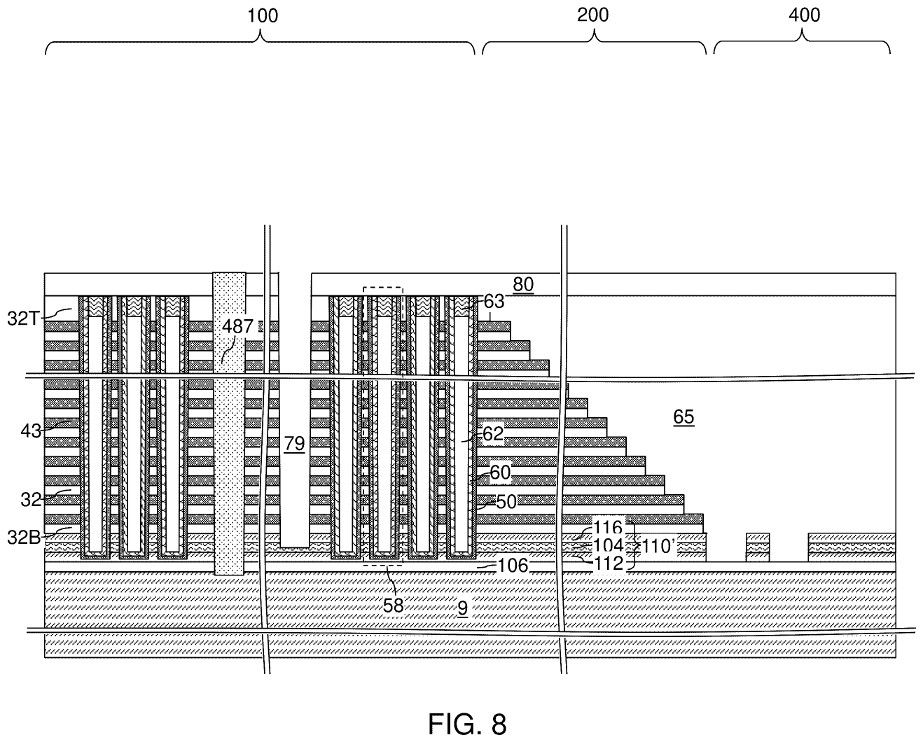

Referring to FIG. 8, a photoresist layer (not shown) can be applied over the contact-level dielectric layer 80, and can be lithographically patterned to cover the sacrificial through-stack opening fill structures 487 without covering the sacrificial lateral isolation trench fill structures 77. The sacrificial lateral isolation trench fill structures 77 can be removed selectively to the materials of the contact-level dielectric layer 80 and the alternating stack (32, 42) to form cavities within the volumes of the lateral isolation trenches 79 (i.e., to reopen the lateral isolation trenches 79).

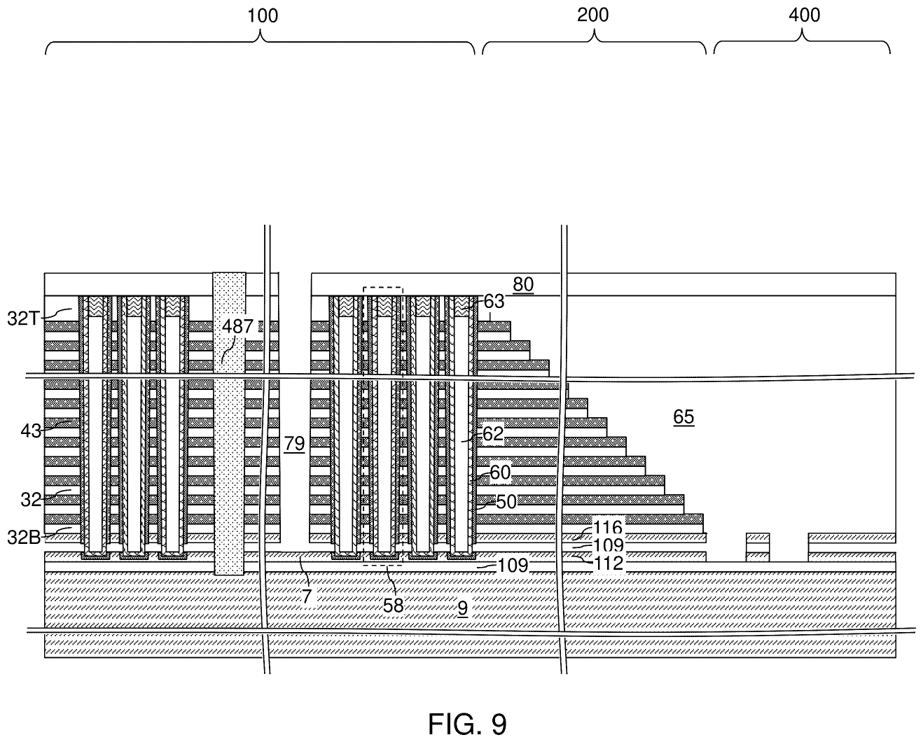

Referring to FIG. 9, an etch-stop spacer (not shown) may be optionally formed on sidewalls of the lateral isolation trenches by depositing and anisotropically etching an etch-stop barrier material, which may comprise silicon oxide or a dielectric metal oxide. An isotropic etch process can be performed to remove the source-level sacrificial layer 104 without removing the contact-level dielectric layer 80, the retro-stepped dielectric material portion 65, the lower source-level semiconductor layer 112, the upper source-level semiconductor layer 116, the upper sacrificial liner 105 (if present), and the lower sacrificial liner 103 (if present). For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selectively to the alternating stack (32, 42), the contact-level dielectric layer 80, the retro-stepped dielectric material portion 65, the lower source-level semiconductor layer 112, and the upper source-level semiconductor layer 116. A source cavity 109 is formed in the volume from which the source-level sacrificial layer 104 is removed.

Wet etch chemicals such as hot TMY and TMAH are selectively to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the lateral isolation trenches 79. Specifically, even if sidewalls of the upper source-level semiconductor layer 116 are physically exposed or even if a surface of the lower source-level semiconductor layer 112 is physically exposed upon formation of the source cavity 109, collateral etching of the upper source-level semiconductor layer 116 and/or the lower source-level semiconductor layer 112 is minimal, and the structural change to the exemplary in-process memory die caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

A sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selectively to at least one source-level semiconductor layer (such as the lower source-level semiconductor layer 112 and the upper source-level semiconductor layer 116) and the vertical semiconductor channels 60.

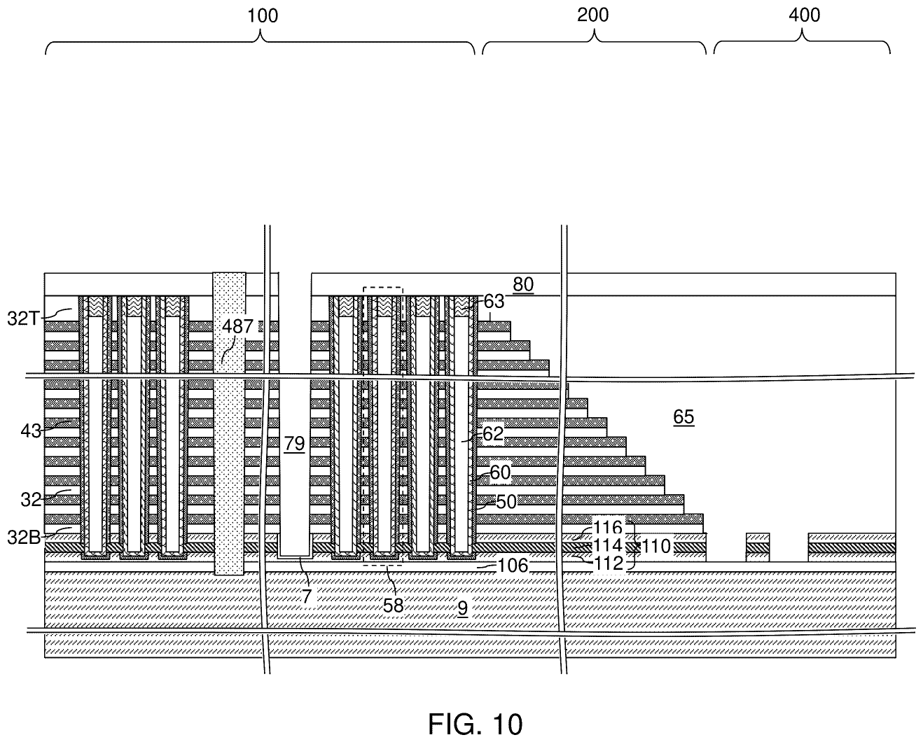

Referring to FIG. 10, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. Optionally, one or more etch back processes may be used in combination with a plurality of selective or non-selective deposition processes to provide a seamless and/or voidless source contact layer 114. Alternatively, the source contact layer 114 can be formed by performing a non-selective doped semiconductor material deposition process such as a low-pressure chemical vapor deposition process. In this case, an etch-back process can be performed to remove portions of the deposited doped semiconductor material that are deposited in the lateral isolation trenches 79 or above the contact-level dielectric layer 80. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³.

The layer stack including the lower source-level semiconductor layer 112, the source contact layer 114, and the upper source-level semiconductor layer 116 constitutes a source layer 110, which replaces the in-process source-level material layers 110′. The source layer 110 contacts a sidewall surface segment of each of the vertical semiconductor channels 60. An oxidation process can be performed to convert physically exposed portions of the semiconductor material layer around bottom portions of the lateral isolation trenches 79. A semiconductor oxide liner 7, such as a silicon oxide liner, can be formed at the bottom of each lateral isolation trench 79.

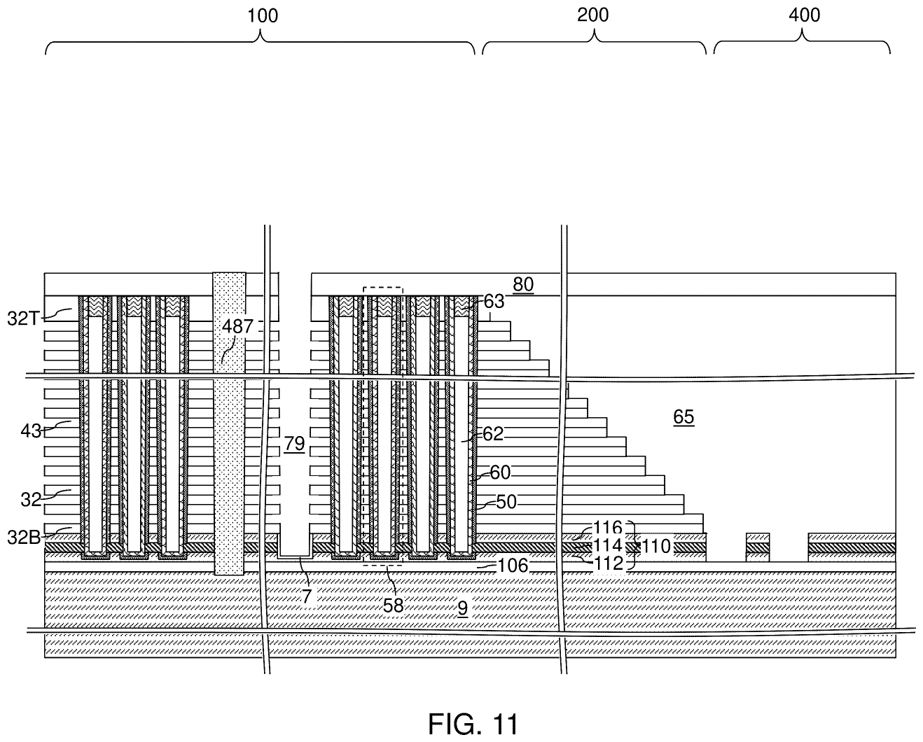

Referring to FIG. 11, an isotropic etch process can be performed to remove the sacrificial material layers 42 selectively to the insulating layers 32, the semiconductor oxide liners 7, the memory opening fill structures 58, and the source layer 110. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing hot phosphoric acid, which is a process in which the exemplary in-process memory die is immersed in phosphoric acid at or near the boiling point of the phosphoric acid. A suitable clean process may be performed as needed. In summary, the laterally-extending cavities 43 can be formed by removing the sacrificial material layers 42 selectively to the insulating layers 32 and the memory opening fill structures 58.

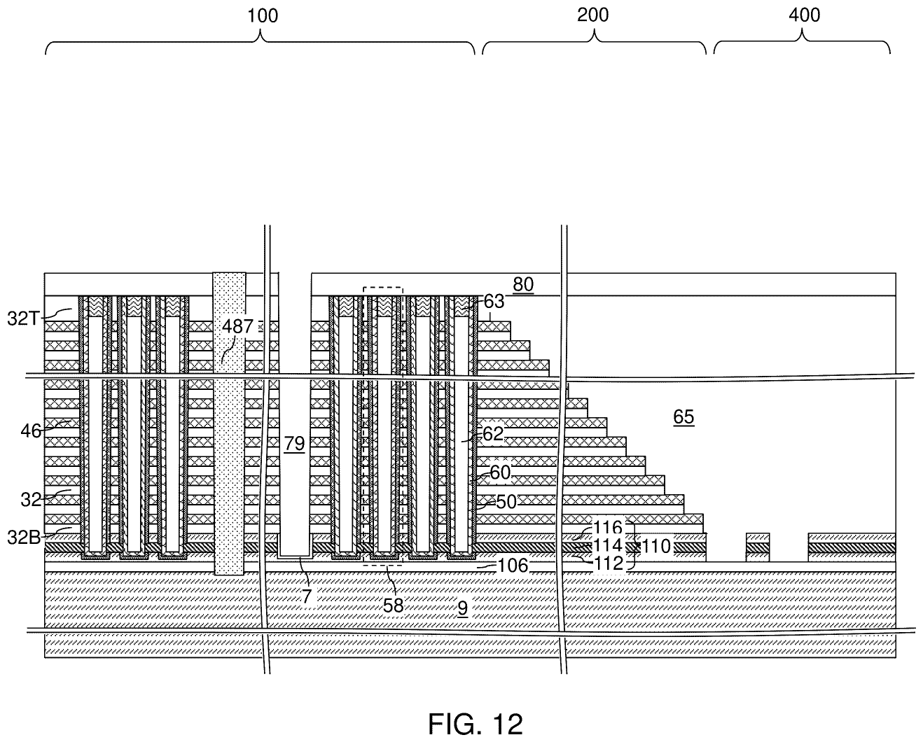

Referring to FIG. 12, a backside blocking dielectric layer (not shown) may be optionally is deposited in the laterally-extending cavities 43. The backside blocking dielectric layer, if employed, includes, and/or consists essentially of, a dielectric metal oxide material. At least one metallic material can be conformally deposited in the laterally-extending cavities 43. The at least one metallic material may comprise a combination of a metallic nitride barrier material and a metallic fill material. For example, the metallic nitride barrier material may comprise TiN, TaN, WN, or MoN, and the metallic fill material may comprise W, Ru, Mo, Co, etc.

An anisotropic etch process can be performed to remove portions of the at least one metallic material and optionally the backside blocking dielectric layer from inside the volumes of the lateral isolation trenches 79 and from above the contact-level dielectric layer 80. Each contiguous remaining portion of the at least one metallic material located within a volume of a respective laterally-extending cavity 43 constitutes an electrically conductive layer 46. Alternating stacks (32, 46) of insulating layers 32 and electrically conductive layers 46 is formed between each neighboring pair of lateral isolation trenches 79. Thus, the alternating stacks (32, 46) of insulating layers 32 and electrically conductive layers 46 can be laterally spaced apart from each other along the second horizontal direction hd2 by the lateral isolation trenches 79.

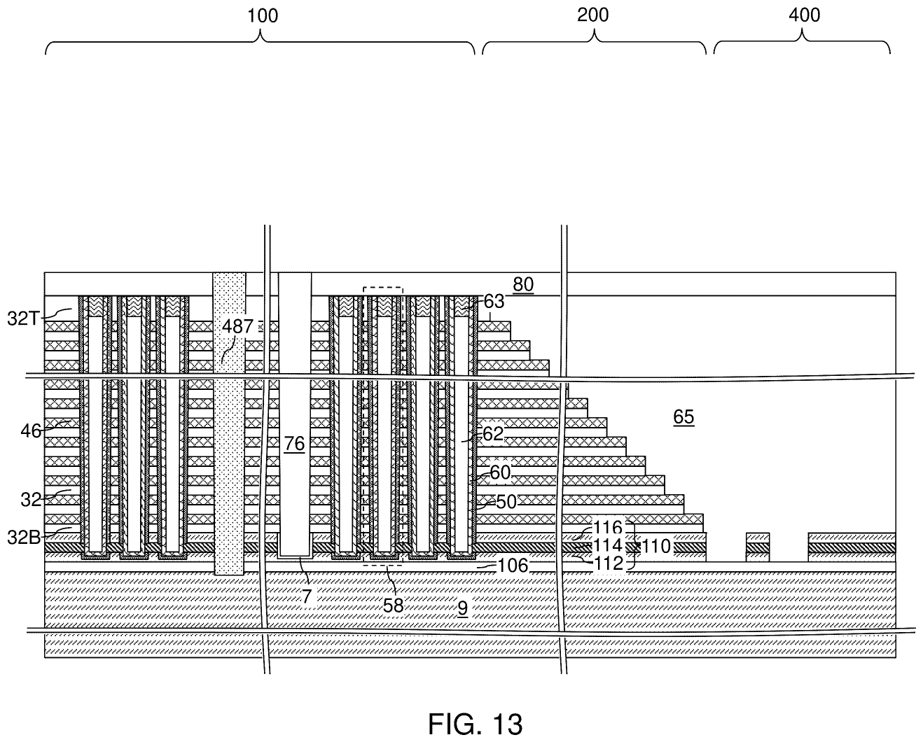

Referring to FIG. 13, an insulating fill material may be conformally deposited in the lateral isolation trenches 79. Excess portions of the insulating fill material may be removed from above the contact-level dielectric layer 80, for example, by a recess etch process.

Each remaining portion of the insulating fill material that fills a respective lateral isolation trench 79 constitutes a lateral isolation trench fill structure 76. Alternatively, each lateral isolation trench fill structure 76 may comprise a combination of a tubular insulating spacer (not expressly shown) and a conductive connection via structure (not expressly shown) that is laterally surrounded by the tubular insulating spacer.

In summary, a lateral isolation trench fill structure 76 having insulating sidewalls can be formed within each lateral isolation trench 79. Each lateral isolation trench fill structure 76 vertically extends from a bottommost surface of an alternating stack (32, 46) to another horizontal plane including a topmost surface of the alternating stack (32, 46).

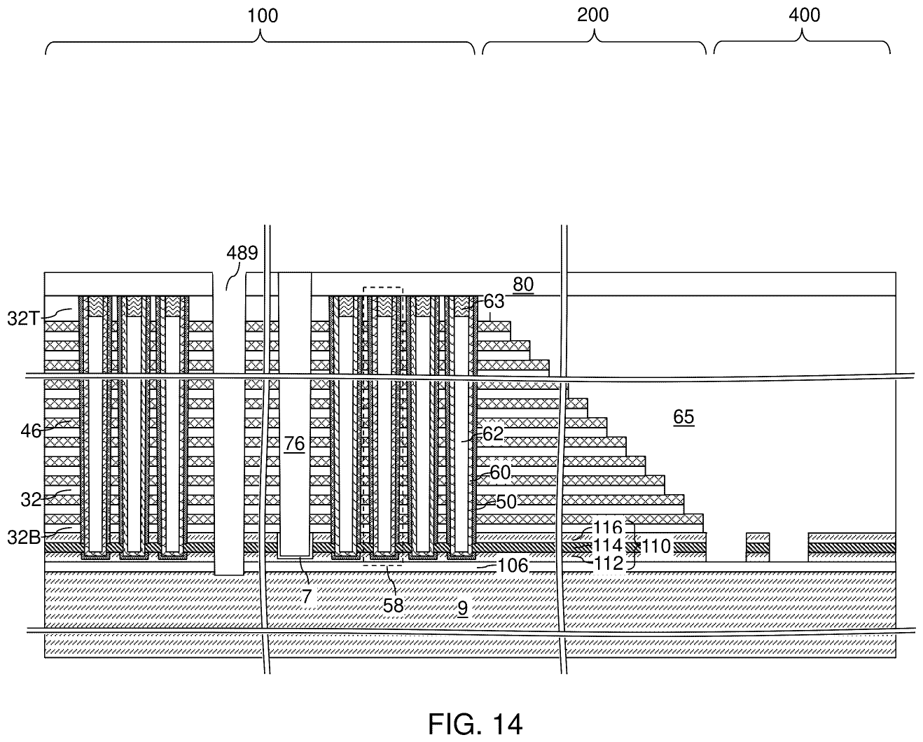

Referring to FIG. 14, a selective etch process can be performed to remove the sacrificial through-stack opening fill structures 487 selectively to the materials of the contact-level dielectric layer 80 and the alternating stacks (32, 42). Cavities are formed in the volumes of the through-stack openings 489.

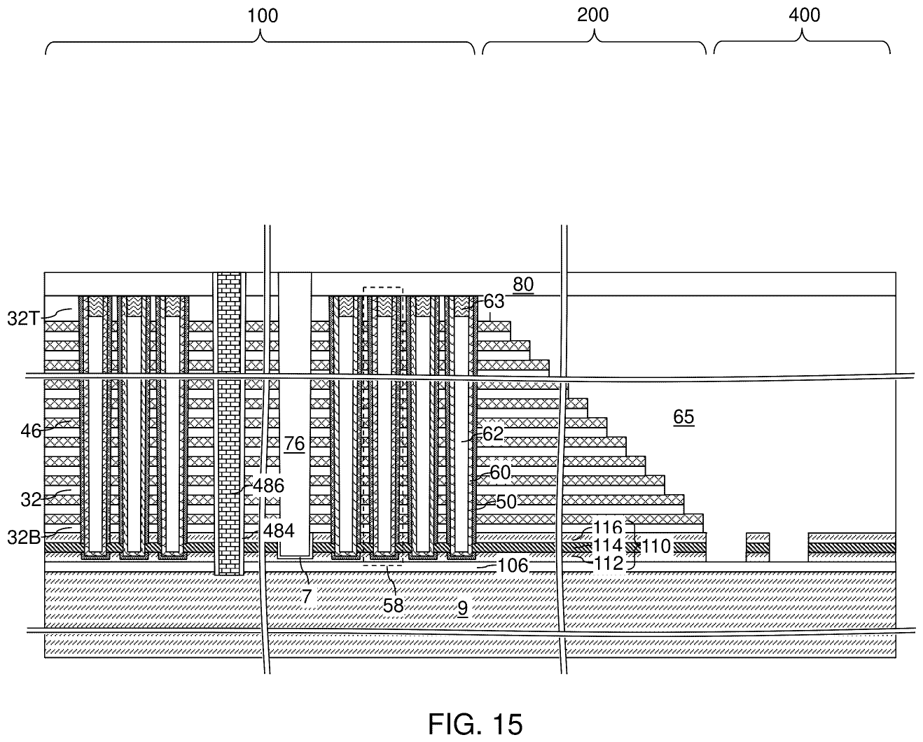

Referring to FIG. 15, a dielectric material, such as silicon oxide, can be conformally deposited in peripheral portions of the through-stack openings 489. An anisotropic etch process can be performed to remove horizontally-extending portions of the deposited dielectric material. Each remaining tubular portion of the deposited dielectric material located in peripheral regions of the through-stack openings 489 constitutes a tubular dielectric spacer 484. The lateral thickness of each tubular dielectric spacer 484 (as measured between an inner sidewall and an outer sidewall) may be in a range from 30 nm to 100 nm, although lesser and greater thicknesses may also be employed.

At least one conductive material, such as at least one metallic material, can be deposited in center regions of the through-stack openings 489. Excess portions of the at least one conductive material can be removed from above the horizontal plane including the top surface of the contact-level dielectric layer 80 by performing a planarization process such as a chemical mechanical planarization process. Each remaining portion of the at least one conductive material that remains in a respective through-stack opening 489 comprises a through-stack via structure 486.

The through-stack via structures 486 are formed in a center region of the in-process memory die. As used herein, the center region is defined as a volume within the in-process memory die that is more proximal to the geometrical center GC of the in-process memory die than to a periphery of the in-process memory die. The periphery is defined by the outer boundary of the in-process memory die in a plan view along a vertical direction.

In one embodiment, at least one of the vertically-extending openings 489 in the alternating stacks (32, 46) is entirely laterally surrounded by a respective one of the alternating stacks (32, 46). In one embodiment, the entirety of at least one of the vertically-extending openings 489 may be located within the area of a respective one of the alternating stacks (32, 46) in the plan view. In one embodiment, at least one of the through-stack via structures 486 is located within a respective one of the vertically-extending openings 489, and is laterally spaced from a sidewall of the respective one of the vertically-extending opening 489 by a respective tubular dielectric spacer 484.

In one embodiment, sidewalls of the through-stack openings 489 may be tapered such that each through-stack opening 489 has a greater lateral dimension at its top than at its bottom. In one embodiment, sidewalls of the through-stack via structures 486 are tapered relative to a vertical direction such that each of the through-stack via structures 486 has a respective variable horizontal cross-sectional area that increases with a vertical distance from the carrier substrate 9.

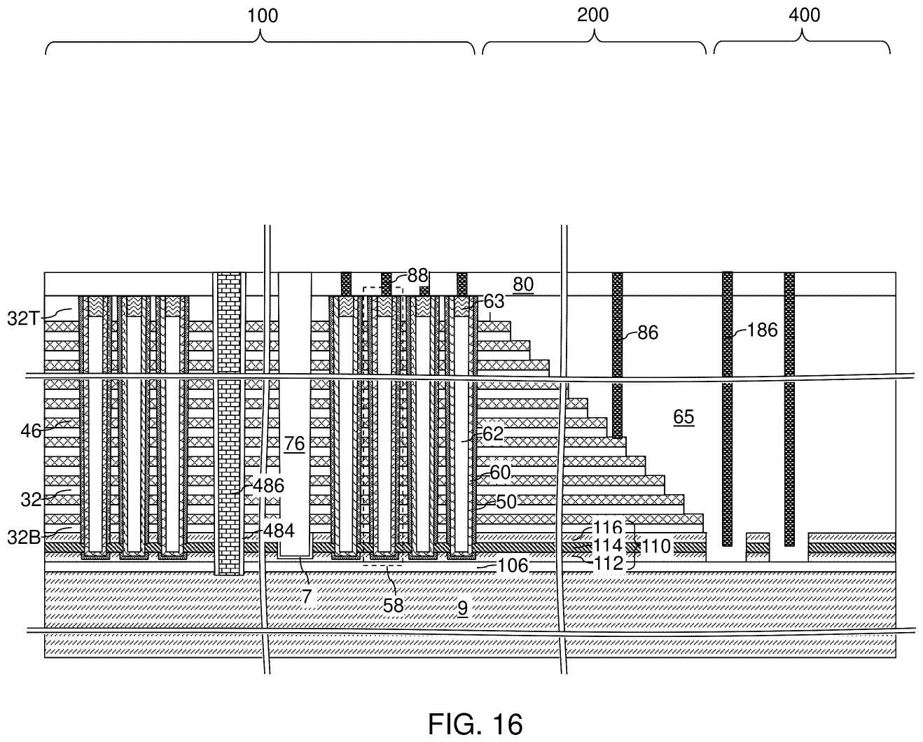

Referring to FIG. 16, a photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the retro-stepped dielectric material portion 65. Drain contact via cavities can be formed through the contact-level dielectric layer 80 over the memory opening fill structures 58. Layer contact via cavities can be formed through the contact-level dielectric layer 80 and the retro-stepped dielectric material portion 65 on a top surface of a respective one of the electrically conductive layers 46. Peripheral edge seal cavities and peripheral connection via cavities can be formed in the peripheral region 400. The photoresist layer can be subsequently removed, for example, by ashing.

At least one conductive material, such as a combination of a metallic barrier material and a metal fill material, can be deposited in the drain contact via cavities, the layer contact via cavities, and peripheral connection via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46. Remaining portions of the at least one conductive material that fill the respective peripheral connection via cavities constitute peripheral connection via structures 186.

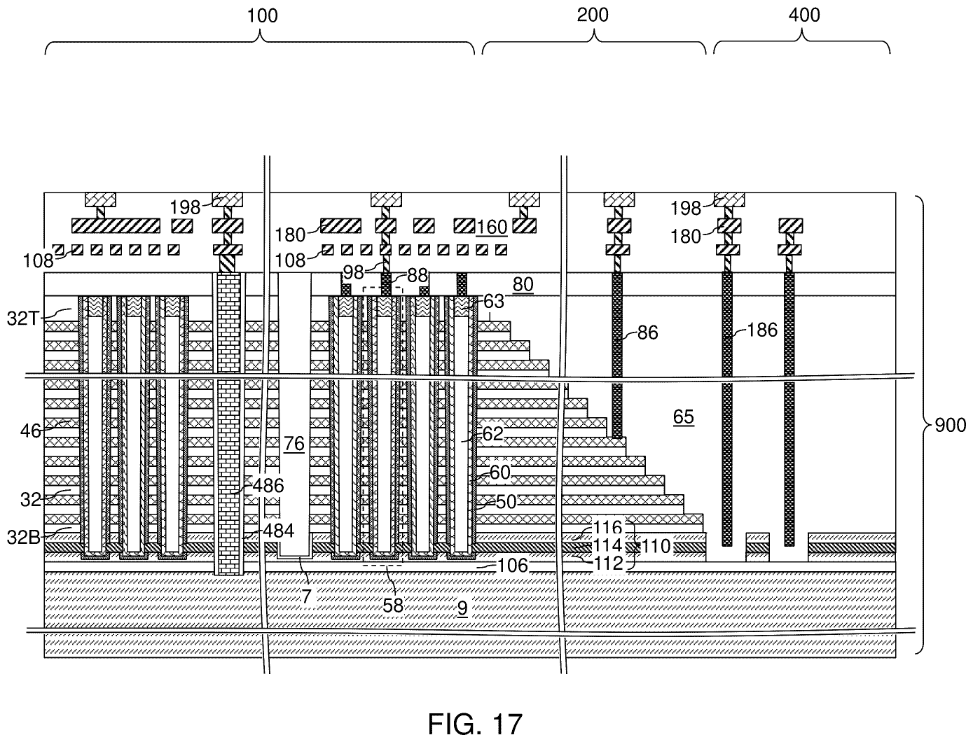

Referring to FIG. 17, additional dielectric material layers embedding metal interconnect structures can be formed over the contact-level dielectric layer 80. The additional dielectric material layers are herein referred to as memory-die front dielectric material layers 160. The metal interconnect structures are herein referred to as memory-die metal interconnect structures (98, 108, 180). The memory-die metal interconnect structures (98, 108, 180) may include bit lines 108 that laterally extend along the second horizontal direction hd2, bit-line-connection via structures 98 that connect the drain contact via structures 88 with the bit lines 108, and additional metal interconnect structures 180 which include various types of metal via structures and various types of metal lines.

Memory-die front bonding structures 198 configured for metal-to-metal bonding can be formed in the topmost dielectric layer of the memory-die front dielectric material layers 160. Metal-to-metal bonding involves direct attachment of contacting metal surfaces to each other without use of any intermediate material. As used herein, “metal-to-metal bonding” refers to the process of directly joining metal surfaces without any intervening adhesive or bonding layer. An exemplary metal-to-metal bonding process comprises a copper-to-copper bonding in which mating copper surfaces are pushed against each other at an elevated temperature, which may be in a range from 200 degrees Celsius to 400 degrees Celsius. In one embodiment, the memory-die front bonding structures 198 may have physically exposed copper surfaces.

The exemplary in-process memory die formation is completed to form a memory die 900, i.e., the final device structure derived from the exemplary in-process memory die. In one embodiment, a two-dimensional array of memory dies 900 may be formed on the same carrier substrate 9. For example, the carrier substrate 9 may comprise a commercially available silicon wafer, and the two-dimensional array of memory dies 900 may comprise a periodic rectangular array of memory dies 900 comprising a respective portion of the silicon wafer and the overlying device layers.

In summary, a plurality of memory dies 900 can be provided. Each of the plurality of memory dies 900 may comprise: an alternating stack (32, 46) of insulating layers 32 and electrically conductive layers 46 that alternate along a vertical direction; a two-dimensional array of memory stack structures 55 each containing a respective vertical semiconductor channel 60 and respective vertical stack of memory elements (comprising portions of the memory material layer 54); and through-stack via structures 486 vertically extending at least from a horizontal plane including a bottommost surface of the alternating stack (32, 46) to another horizontal plane including a topmost surface of the alternating stack (32, 46).

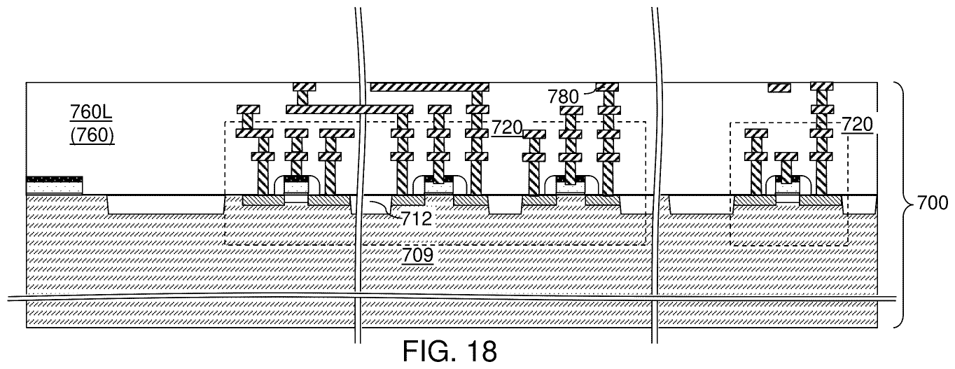

Referring to FIG. 18, an exemplary memory-controller die (e.g., logic die) 700 is illustrated. The exemplary memory-controller die 700 may be provided within a unit area in a substrate, such as a semiconductor (e.g., silicon) wafer including a two-dimensional array of memory-controller dies 700. The exemplary memory-controller die 700 comprises a substrate, such as a semiconductor substrate 709, which is also referred to as a controller-die semiconductor substrate. The semiconductor substrate 709 may comprise a silicon wafer. Shallow trench isolation structures 712 can be formed in an upper portion of the semiconductor substrate 709. A memory controller circuit 720, which is also referred to as a peripheral circuit or driver circuit, can be formed on and/or over the top surface of the semiconductor substrate 709.

The memory controller circuit 720 is configured to control operation of the memory array within the memory die 900. For example, the memory controller circuit 720 may comprise word line drivers configured to drive word lines, which are a subset of the electrically conductive layers 46 within the alternating stacks (32, 46). The memory controller circuit 720 may comprise bit line drivers configured to drive the bit lines 108 in the memory die 900. For example, as described with reference to the memory die 900, the bit lines 108 of a memory die 900 may be electrically connected to first ends (i.e., the ends that are connected to the drain regions 63) of a respective subset of the memory stack structures 55. The memory controller circuit 720 may comprise source line drivers configured to drive one or more source layers to be subsequently formed on the memory die 900 after removal of the carrier substrate 9. The memory controller circuit 720 may also comprise input/output control circuits configured to receive input data from, or to transmit output data to, at least one conductive pad (which may be a bonding structure) to be subsequently formed on the through-stack via structures 486 after removal of the carrier substrate 9. Generally, the memory controller circuit 720 may comprise any electronic circuit configured to manage data flow, handle read and write operations, ensure data integrity through error correction, perform wear leveling to extend memory lifespan, and/or support communication protocols for interfacing with external devices and systems for the three-dimensional memory array in the memory die 900.

Controller-die front metal interconnect structures 780 embedded within controller-die front dielectric material layers 760 can be formed over the memory controller circuit 720. Specifically, a first subset of the controller-die front metal interconnect structures 780 embedded within a first subset of the controller-die front dielectric material layers 760 can be formed. The first subset of the controller-die front dielectric material layers 760 is herein referred to as lower controller-die front dielectric material layers 760L. In the illustrated example in FIG. 18, the lower controller-die front dielectric material layers 760L comprise four via-level dielectric material layers and four line-level dielectric material layers. Generally, the total number of line levels within the lower controller-die front dielectric material layers 760L may be in a range from 1 to 12.

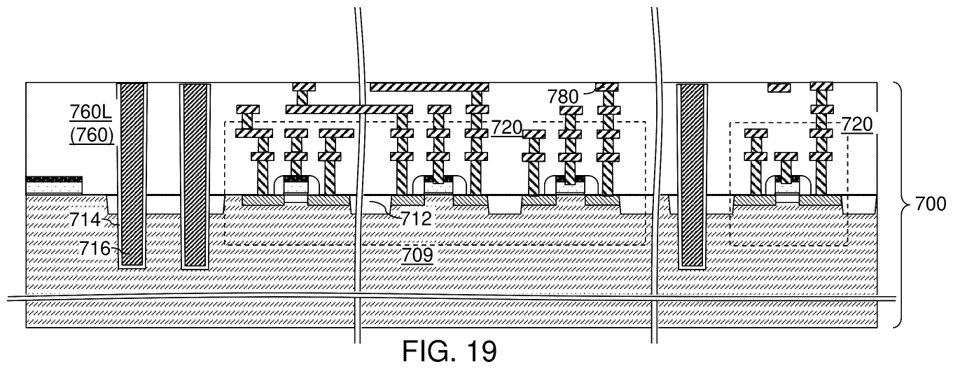

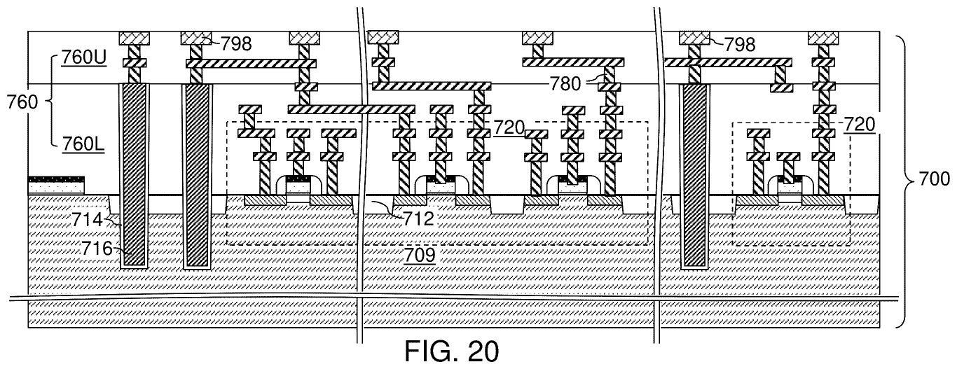

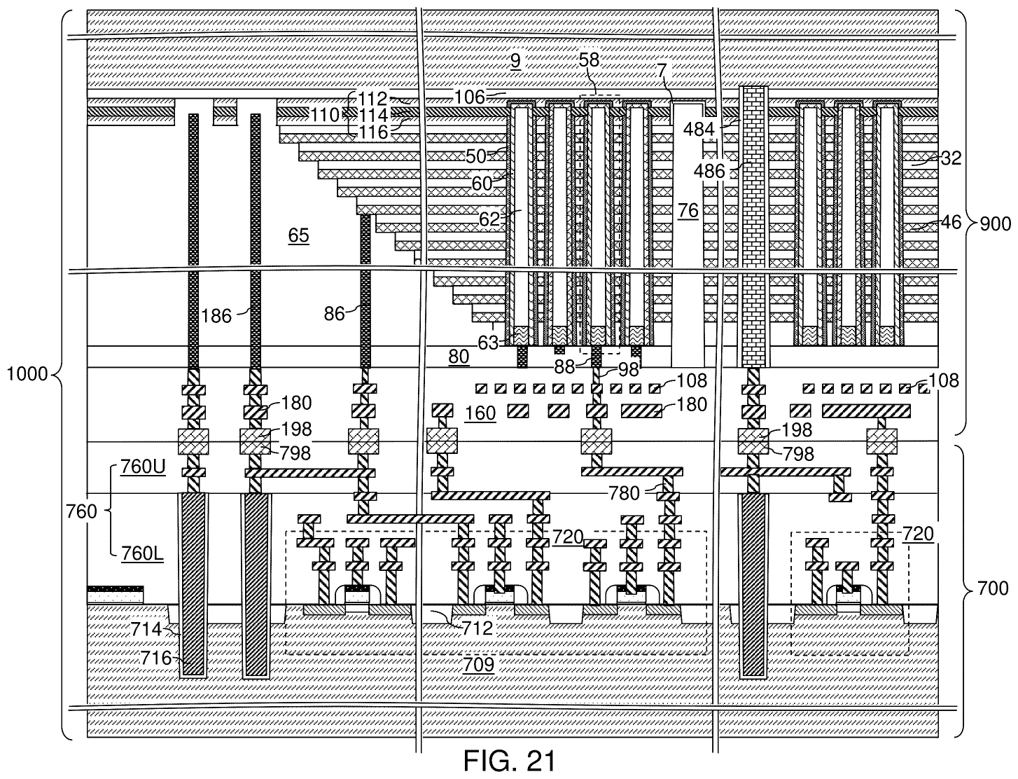

Referring to FIG. 19, a photoresist layer (not shown) can be applied over the top surface of the lower controller-die front dielectric material layers 760L, and can be lithographically patterned to form openings in areas that do not overlap with the controller-die front metal interconnect structures 780 that are embedded within the lower controller-die front dielectric material layers 760L. An anisotropic etch process can be performed to form via cavities that vertically extend through the lower controller-die front dielectric material layers 760L and an upper portion of the semiconductor substrate 709. Upon thinning of the semiconductor substrate 709 in a subsequent processing step, the via cavities vertically extend through the thinned semiconductor substrate 709, and as such, the via cavities are herein referred to as through-substrate via cavities. The depth of the bottom surfaces of the through-substrate via cavities, as measured from the horizontal plane including the top surface of the semiconductor substrate 709, may be in a range from 5 microns to 30 microns, although lesser and greater depths may also be employed. The photoresist layer can be subsequently removed, for example, by ashing.

A dielectric spacer material, such as silicon oxide, can be conformally deposited in peripheral regions of the through-substrate via cavities. A metallic fill material such as copper, tungsten, titanium, tantalum, and/or molybdenum may be deposited in remaining volumes of the through-substrate via cavities. Excess portions of the metallic fill material and the dielectric spacer material can be removed from above the horizontal plane including the top surface of the lower controller-die front dielectric material layers 760L. Each remaining portion of the dielectric spacer material comprises a dielectric spacer 714. The thickness of each dielectric spacer 714 may be in a range from 20 nm to 100 nm, although lesser and greater thicknesses may also be employed. Each remaining portion of the metallic fill material comprises a through-substrate via (TSV) structure 716, such as a through-silicon via structure. Each TSV structure 716 may have a respective top surface within a horizontal plane including top surfaces of a subset of the controller-die front metal interconnect structures 780, and may have a respective bottom surface located within a horizontal plane located between a top surface of the semiconductor substrate 709 and a bottom surface of the semiconductor substrate 709.

Referring to FIG. 20, a second subset of the controller-die front metal interconnect structures 780 embedded within a second subset of the controller-die front dielectric material layers 760 can be formed. The second subset of the controller-die front dielectric material layers 760 is herein referred to as upper controller-die front dielectric material layers 760U. In the illustrated example in FIG. 20, the upper controller-die front dielectric material layers 760U comprise a via-level dielectric material layer and two line-level dielectric material layers. Generally, the total number of line levels within the upper controller-die front dielectric material layers 760U may be in a range from 1 to 12.

Bonding structures configured for metal-to-metal bonding can be formed in the topmost layer among the controller-die front dielectric material layers 760. These bonding structures are herein referred to as controller-die front bonding structures 798. The controller-die front bonding structures 798 can be electrically connected to a respective electrical node of the memory controller circuit 720, and can be arranged in a pattern that is a mirror image pattern of the memory-die front bonding structures 198 of the memory die 900. In one embodiment, each memory-controller die 700 may be provided within a unit die area in a semiconductor wafer including a two-dimensional array of memory-controller dies 700.

A plurality of memory-controller dies 700 may be provided. Each memory-controller die 700 comprises a respective semiconductor substrate 709, a respective memory controller circuit 720 including a respective set of semiconductor devices located on a front surface of the respective semiconductor substrate 709; respective controller-die front dielectric material layers 760 embedding respective controller-die front metal interconnect structures 780 and located on the respective set of semiconductor devices; respective controller-die front bonding structures 798 that are embedded within the controller-die front dielectric material layers 760; and respective TSV structures 716 that vertically extend through a subset of the respective controller-die front dielectric material layers 760 and an upper portion of the respective semiconductor substrate 709.

Referring to FIG. 21, a unit bonded assembly 1000 can be formed by bonding the memory-controller die 700 described with reference to FIG. 20 with the memory die 900 described with reference to FIG. 17. A plurality of unit bonded assemblies 1000 can be formed. Each of the plurality of unit bonded assemblies 1000 constitutes a bonded assembly 1000. The memory-controller die 700 can be attached to the memory die 900 by bonding the controller-die front bonding structures 798 to the memory-die front bonding structures 198. The bonding between mating pairs of a respective memory die 900 and a respective memory-controller die 700 may be performed employing a wafer-to-wafer bonding process in which a two-dimensional array of memory dies 900 is bonded to a two-dimensional array of memory-controller dies 700, by a die-to-wafer bonding process (in which a diced die is bonded to a wafer), or by a die-to-die bonding process (in which two diced dies are bonded to each other). The controller-die front bonding structures 798 within each memory-controller die 700 can be bonded to the memory-die front bonding structures 198 within a respective memory die 900 by metal-to-metal bonding, such as copper-to-copper bonding.

The memory die 900 comprises alternating stacks (32, 46) of insulating layers 32 and electrically conductive layers 46 and memory-die front dielectric material layers 160 embedding memory-die metal interconnect structures (180, 108, 98) and memory-die front bonding structures 198. Memory stack structures 55 vertically extend through a respective one of the alternating stacks (32, 46) in a memory array region 100, and layer contact via structures 86 contact a respective electrically conductive layer 46 within the alternating stacks (32, 46) in a contact region 200. In one embodiment, through-stack via structures 486 vertically extend through vertically-extending openings 489 in the alternating stacks (32, 46) within a center region of the memory die 900, which is defined as a volume within the memory die 900 that is more proximal to a geometrical center GC of the memory die 900 than to a periphery of the memory die 900 defined by outer sidewalls of the memory die 900 in a plan view along a vertical direction. A memory-controller die 700 comprises a memory controller circuit 720 including a control circuitry for controlling operation of the electrically conductive layers 46 and further comprises controller-die front dielectric material layers 760 embedding controller-die front metal interconnect structures 780 and controller-die front bonding structures 798. The controller-die front bonding structures 798 are bonded to the memory-die front bonding structures 198.

Within each bonded assembly 1000 (i.e., a unit bonded assembly 1000) of a respective memory die 900 and a respective memory-controller die 700, the respective memory die 900 comprises respective memory-die front bonding structures 198 embedded within respective memory-die front dielectric material layers 160, and the respective memory-controller die 700 comprises respective controller-die front bonding structures 798 embedded within respective controller-die front dielectric material layers 760 and bonded to the respective memory-die front bonding structures 198. In one embodiment, the respective controller-die front bonding structures 798 are bonded to the respective memory-die front bonding structures 198 via metal-to-metal bonding, such as copper-to-copper bonding.

In one embodiment, dielectric-to-dielectric bonding, such as silicon oxide-to-silicon oxide bonding may be employed in conjunction with the metal-to-metal bonding. In this case, a topmost memory-die front dielectric material layer of the respective memory-die front dielectric material layers 160 is bonded to a topmost controller-die front dielectric material layer among the controller-die front dielectric material layers 760 via dielectric-to-dielectric bonding (i.e., hybrid bonding is used to bond the respective memory die to the respective memory-controller die).

In one embodiment, the respective memory die 900 includes a respective three-dimensional array of memory elements (e.g., flash memory cells comprising as portions of a memory material layer 54), and the respective memory-controller die 700 includes a respective memory controller circuit 720 configured to control operation of the respective three-dimensional array of memory elements. In one embodiment, a subset of the through-stack via structures 486 is electrically connected to a subset of semiconductor devices (e.g., input/output control devices, such as field effect transistors) in the respective memory controller circuit 720 of the memory-controller die 700 through a subset of the memory-die metal interconnect structures (180, 108, 98) and through a subset of the controller-die front metal interconnect structures 780.

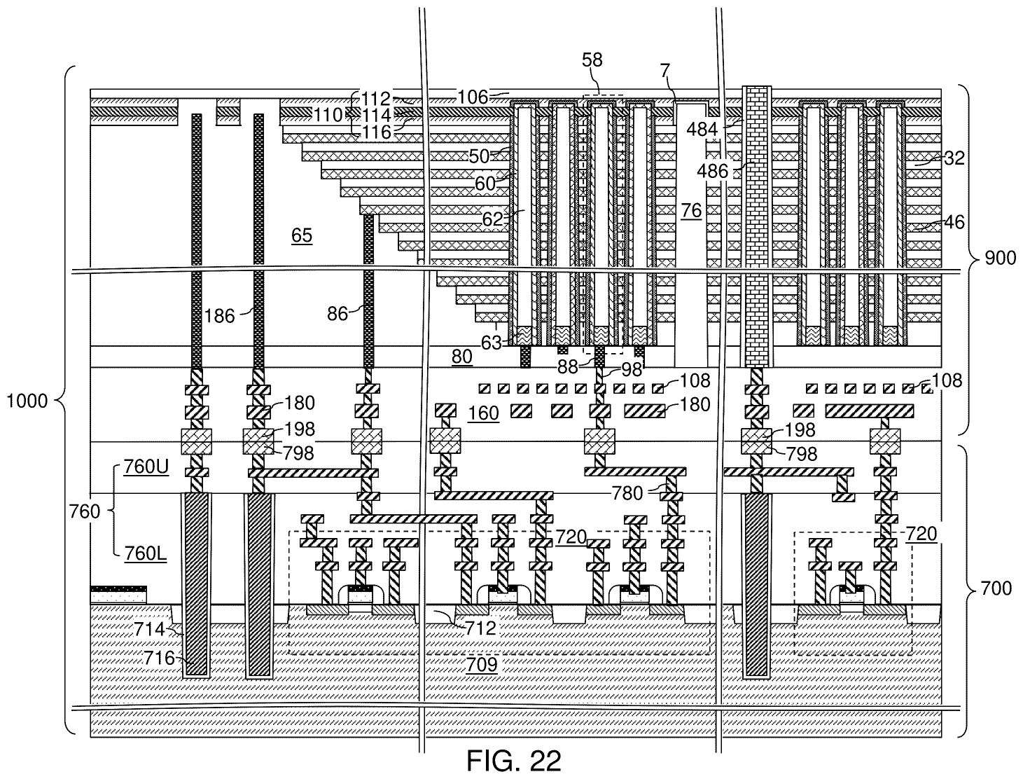

Referring to FIG. 22, the carrier substrate 9 may be removed, for example, by grinding, polishing, cleaving, an isotropic etch process, and/or an anisotropic etch process. If a polishing process such as a chemical mechanical polishing process is employed to remove the carrier substrate 9, the first memory-die proximal inorganic dielectric layer 106 may be subsequently employed as a polishing stopper material layer. If an etch process such as a wet etch process is employed to remove the carrier substrate 9, the first memory-die proximal inorganic dielectric layer 106 may be subsequently employed as an etch stop material layer. End surfaces of the through-stack via structures 486 may be physically exposed upon removal of the carrier substrate 9.

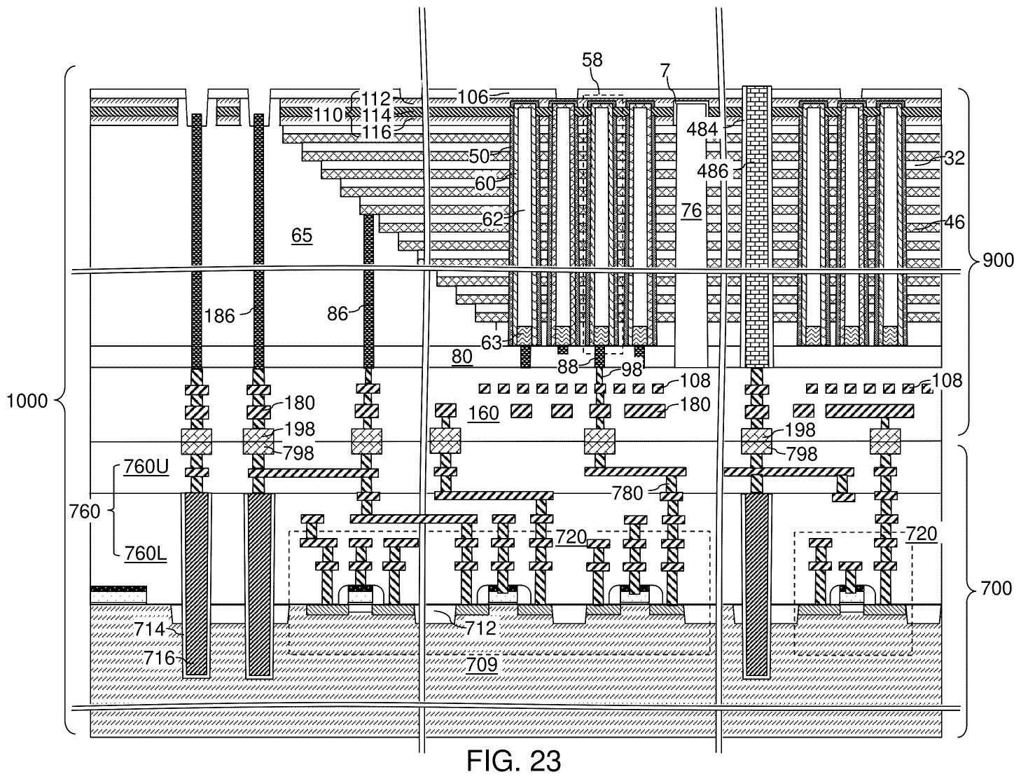

Referring to FIG. 23, backside via openings can be formed through the first memory-die proximal inorganic dielectric layer 106 on the backside surface (i.e., a distal surface) of the source layer 110 by performing a combination of a lithographic patterning process and an anisotropic etch process. Additional backside via openings can be formed through the first memory-die proximal inorganic dielectric layer 106 and through the source layer 110 over the end portions of the peripheral connection via structures 186 by performing a combination of an additional lithographic patterning process and an additional anisotropic etch process.

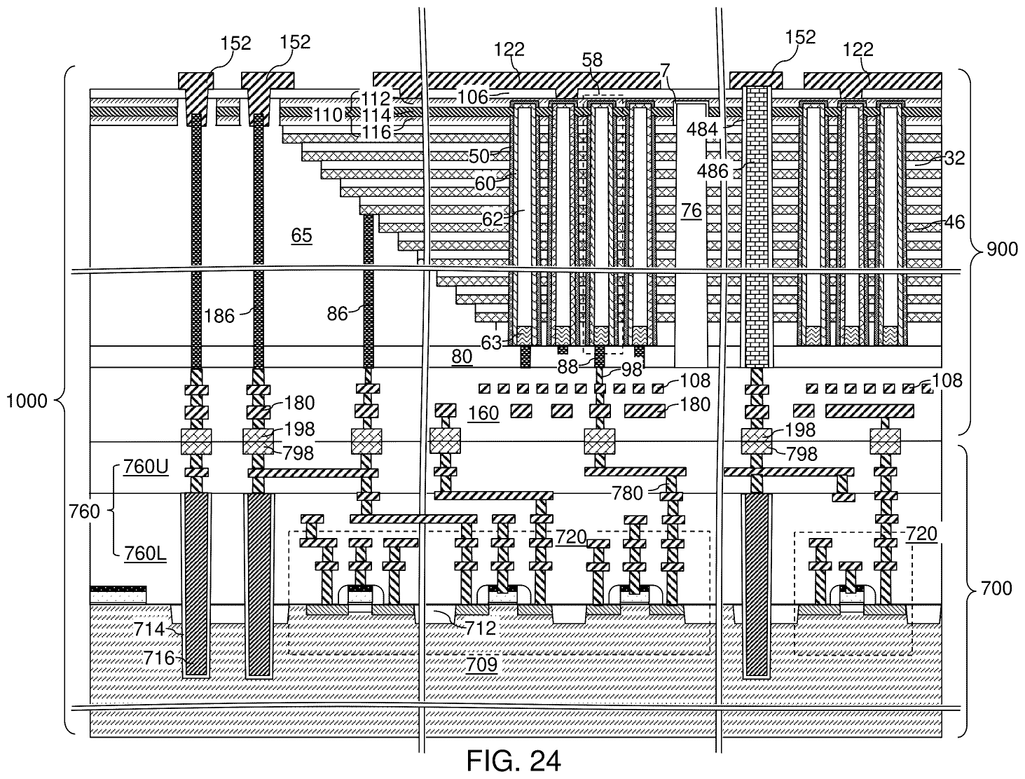

Referring to FIG. 24, at least one electrically conductive material can be deposited in the openings, over the distal surface of the first memory-die proximal inorganic dielectric layer 106, and over end portions of the memory stack structures 55 that are distal from an interface between the memory die 900 and the memory-controller die 700 to form a backside conductive layer. The at least one electrically conductive material may comprise a combination of a metallic barrier material (such as TiN, TaN, WN, and/or MoN) and an aluminum-based material comprising aluminum at an atomic percentage greater than 90%. The backside conductive layer can be subsequently patterned to form various proximal memory-die metal interconnect structures (122, 152) that are composed primarily of aluminum.

In one embodiment, the proximal memory-die metal interconnect structures (122, 152) may comprise at least one source connection structure 122 and aluminum pad structures 152. Each of the at least one source connection structure 122 may be electrically connected to a respective source line driver through a respective metal via structure 186 vertically extending through the retro-stepped dielectric material portion 65, a respective subset of the memory-die metal interconnect structures 180, a respected bonded pair of a controller-die front bonding structure 798 and a memory-die front bonding structure 198, and a respective subset of the controller-die front metal interconnect structures 780. Each source connection structure 122 is electrically connected to the end portions of a respective subset of the memory stack structures 55 (e.g., to source side end portions of the vertical semiconductor channels 60). Each of the peripheral connection via structures 186 may be physically and/or electrically connected to a respective one of the aluminum pad structures 152 or the source connection structure 122. Each of the through-stack via structures 486 may be physically and/or electrically connected to a respective one of the aluminum pad structures 152 or the source connection structure 122.

At least a subset of the aluminum pad structures 152 can be electrically connected to a respective electrical node of the memory controller circuit 720 through a respective peripheral connection via structure 186, a respective subset of the memory-die metal interconnect structures 180, a respected bonded pair of a controller-die front bonding structure 798 and a memory-die front bonding structure 198, and a respective subset of the controller-die front metal interconnect structures 780. Optionally, an additional subset of the aluminum pad structures 152 can be electrically connected to a respective electrical node of the memory controller circuit 720 through a respective through-stack via structure 486, a respective subset of the memory-die metal interconnect structures 180, a respected bonded pair of a controller-die front bonding structure 798 and a memory-die front bonding structure 198, and a respective subset of the controller-die front metal interconnect structures 780.

Wafer-level die sorting (D/S) is then performed using one or more of the aluminum pad structures 152. Specifically, an electrical probe is contacted to one or more of the aluminum pad structure to conduct electrical testing of one or more of the memory die 900 of the bonded assembly (700, 900). Since the aluminum material of the aluminum pad structure is harder than copper material of the bonding pads, no damage or a reduced amount of damage is caused by the D/S testing than if the electrical probe is contacted to a relatively soft copper bonding pad. Thus, the number of probe marks left by the testing process is reduced or the probe marks are eliminated.

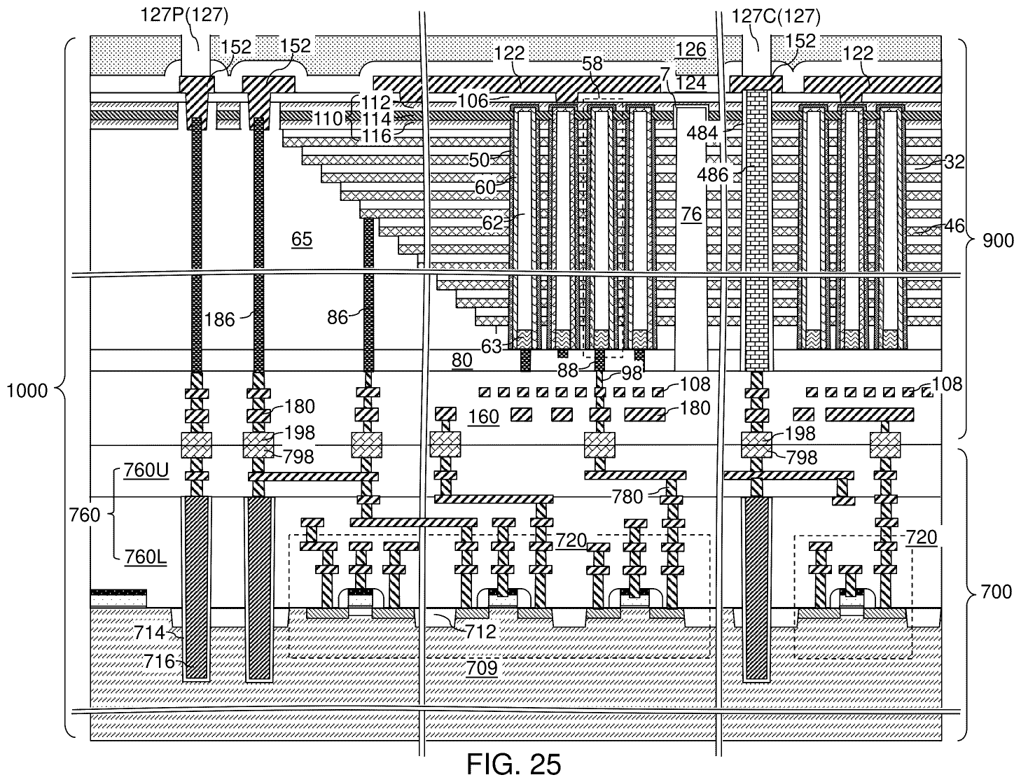

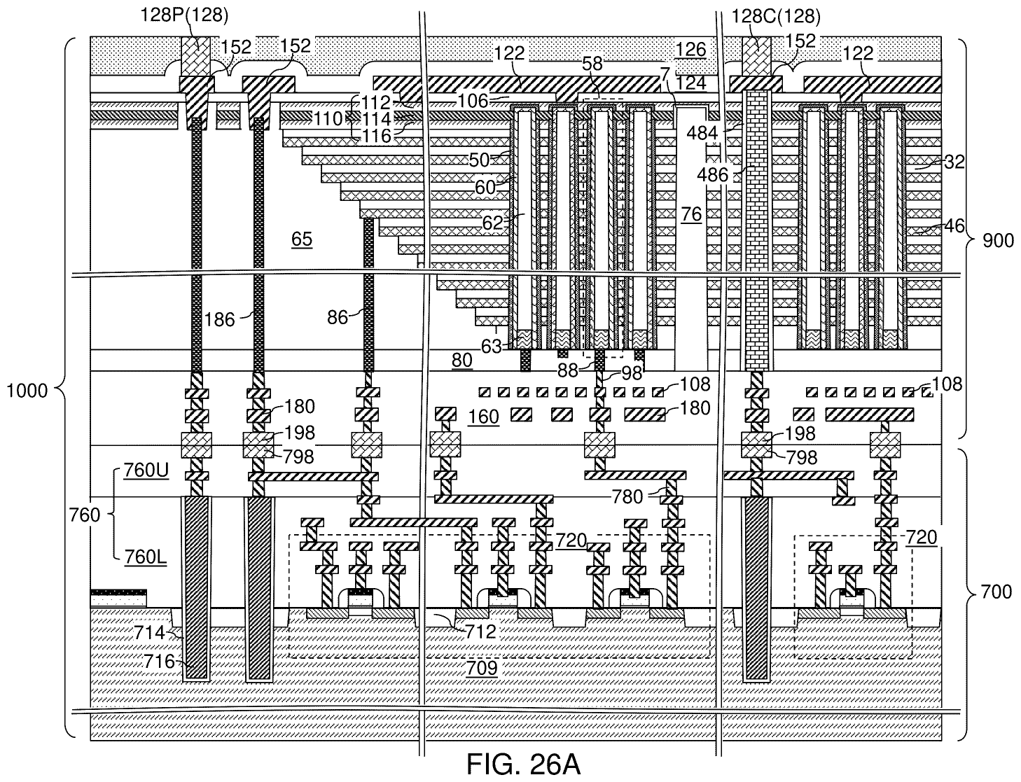

Referring to FIG. 25, after the D/S testing, at least one second memory-die proximal inorganic dielectric layer 124 can be formed over the at least one source connection structure 122 and the aluminum pad structures 152. The at least one second memory-die proximal inorganic dielectric layer 124 comprises at least one inorganic dielectric layer. For example, the at least one second memory-die proximal inorganic dielectric layer 124 may comprise a stack of a stack of a first silicon oxide passivation layer, a silicon nitride passivation layer, and a third silicon oxide passivation layer. Generally, any combination of one or more inorganic interlayer dielectric (ILD) material layers may be employed for the at least one second memory-die proximal inorganic dielectric layer 124. In one embodiment, the entirety of the first memory-die proximal inorganic dielectric layer 106 and the at least one second memory-die proximal inorganic dielectric layer 124 may consist essentially of inorganic dielectric materials, such as silicon oxide, silicon nitride, silicon oxynitride, silicon carbonitride, and/or at least one dielectric metal oxide. The proximal memory-die metal interconnect structures (122, 152) can be embedded within the memory-die proximal inorganic dielectric layers (106, 124).

A polymer dielectric layer 126 can be applied over the memory-die proximal inorganic dielectric layers (106, 124). According to an aspect of the present disclosure, the polymer dielectric layer 126 comprises a polymer dielectric material that can be subsequently employed for a polymer-to-polymer bonding. As used herein, a polymer-to-polymer bonding refers to a state of a bonded structure or a process of forming a bonded structure in which two polymer dielectric layers are physically and/or chemically bonded to each other. A polymer-to-polymer bonding can be achieved by applying heat and/or pressure to a bonding interface between two polymer materials of the same material composition or different material compositions. Exemplary polymer materials that may be employed for the polymer dielectric layer 126 comprise polyimide, benzocyclobutene (BCB), or an epoxy-based resin. The polymer dielectric layer 126 may be deposited, for example, by spin coating or spray coating. The entirety of the top surface of the as-deposited polymer dielectric layer 126 may be planar, i.e., formed within a horizontal plane. Alternatively, a CMP process may be performed to planarize the top surface of the polymer dielectric layer 126. The thickness of the polymer dielectric layer 126 may be in a range from 1 micron to 15 microns, such as from 3 microns to 10 microns, although lesser and greater thicknesses may also be employed.

In one embodiment, polymer dielectric layer 126 can be patterned to form openings over the areas of the aluminum pad structures 152. If the polymer dielectric layer 126 comprises a photosensitive material, the polymer dielectric layer 126 can be lithographically exposed and developed to form the openings therein. An anisotropic etch process can be performed to transfer the pattern of the openings in the polymer dielectric layer through the at least one second memory-die proximal inorganic dielectric layer 124.

The aluminum pad structures 152 may be employed as etch stop structures. Pad cavities 127 can be formed through the polymer dielectric layer 126 and the at least one second memory-die proximal inorganic dielectric layer 124.

If the polymer dielectric layer 126 comprises a non-photosensitive material, a photoresist layer (not shown) can be applied over the polymer dielectric layer 126, and can be lithographically patterned to form openings therein. An anisotropic etch process can be performed to transfer the pattern of the openings in the photoresist layer through the polymer dielectric layer 126 and the at least one second memory-die proximal inorganic dielectric layer 124. The aluminum pad structures 152 may be employed as etch stop structures. Pad cavities 127 can be formed through the polymer dielectric layer 126 and the at least one second memory-die proximal inorganic dielectric layer 124. Any remaining portion of the photoresist layer may be removed, for example, by ashing.

The pad cavities 127 may comprise central memory-die pad cavities 127C that overlie aluminum pad structures 152 that are connected to the through-stack via structures 486, and peripheral memory-die pad cavities 127P that overlie aluminum pad structures 152 that are connected to the peripheral connection via structures 186. In one embodiment, each pad cavity 127 may comprise a respective sidewall that laterally encloses a respective void and vertically extends straight from a top surface of an aluminum pad structure 152 to a top surface of the polymer dielectric layer 126.

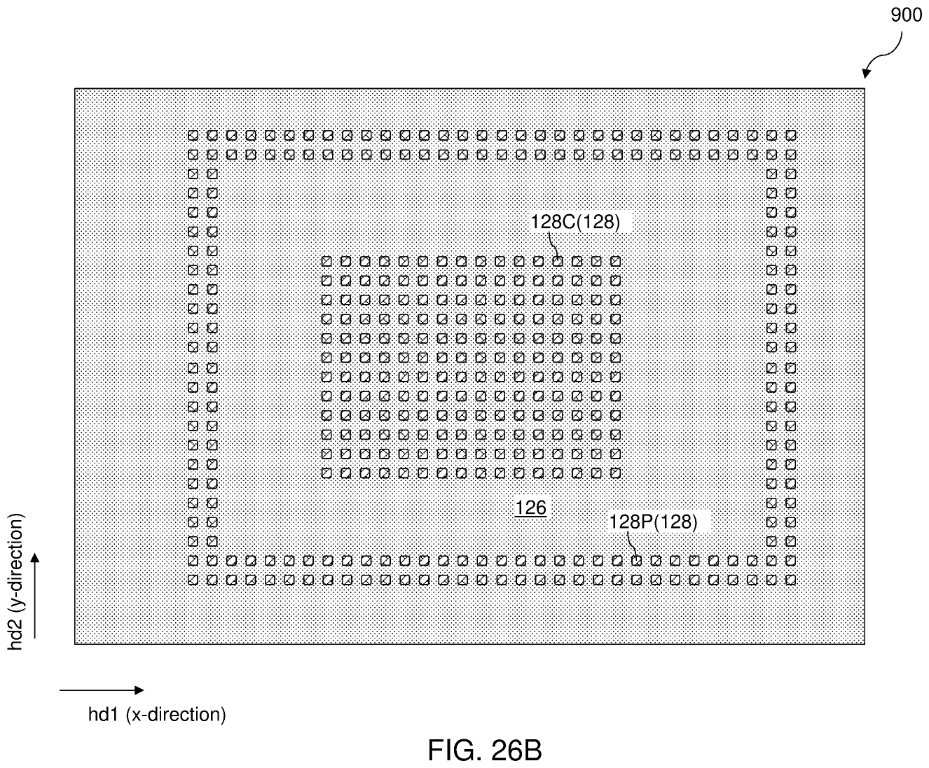

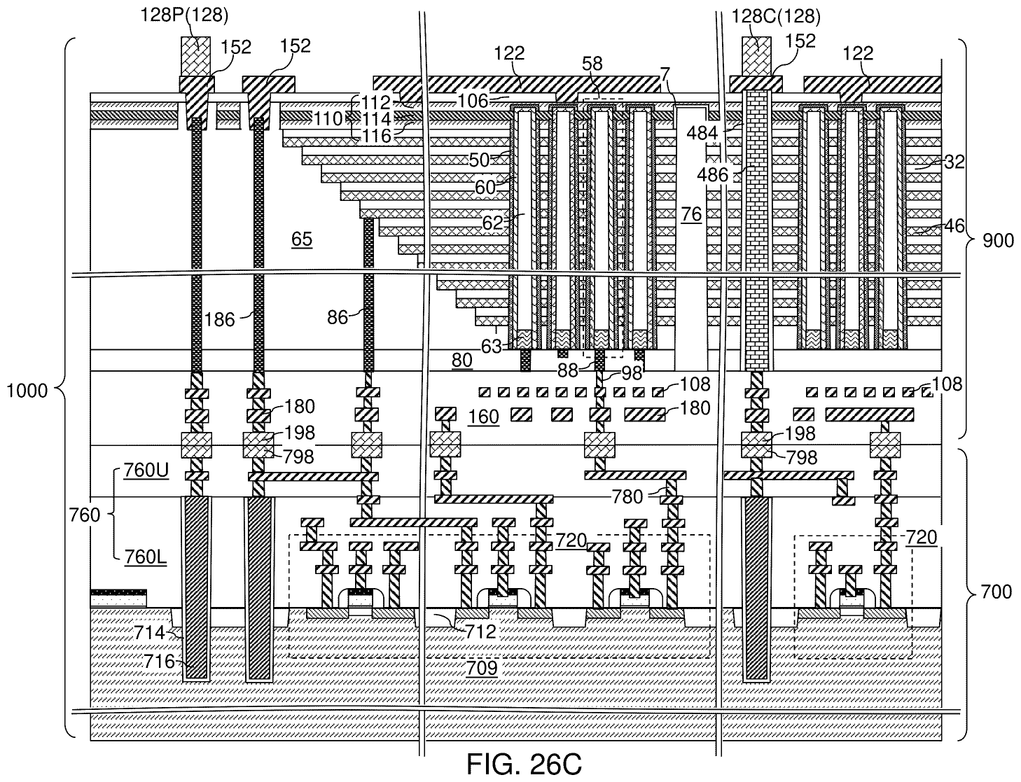

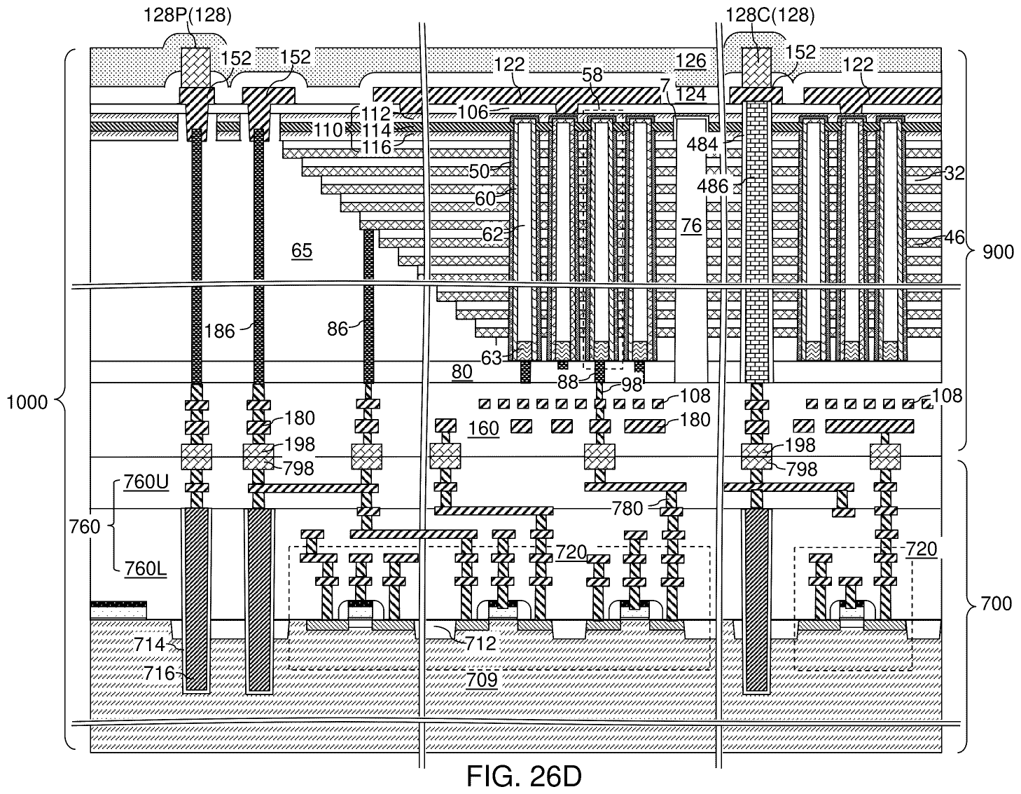

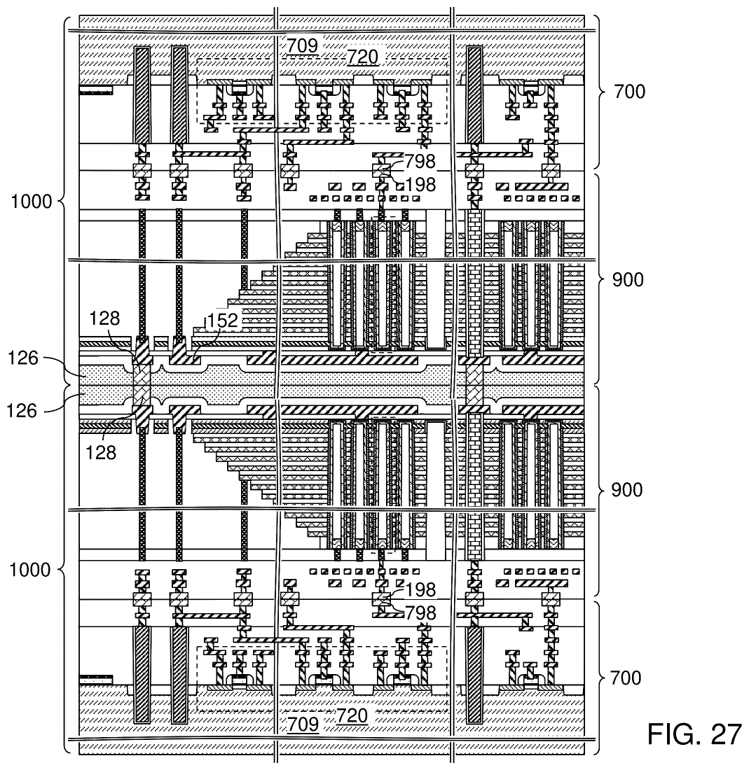

Referring to FIGS. 26A and 26B, an optional conductive base layer may be deposited by at least one physical vapor deposition process and/or at least one chemical vapor deposition process. The conductive base layer may comprise a combination of a conductive metallic barrier liner and a copper seed layer. The conductive metallic barrier liner may comprise at least one conductive metallic barrier material such as TiN, TaN, WN, MoN, Ti, and/or Ta, and may have a thickness in a range from 20 nm to 100 nm, although lesser and greater thicknesses may also be employed. The copper seed layer may be deposited on the conductive metallic barrier liner by physical vapor deposition, and may consist essentially of copper. The thickness of the copper seed layer may be in a range from 20 nm to 300 nm, although lesser and greater thicknesses may also be employed. Subsequently, copper may be plates (e.g., deposited by electroplating or electroless plating) on the copper seed layer to form an electroplated copper layer. Alternatively, if the metallic barrier and/or seed layer are omitted, then copper may be plated directly on the aluminum pad structure 152 and/or on the metallic barrier layer (if present). The duration of the plating process can be selected such that the plated copper layer fills the entirety of remaining voids in the pad cavities 127. A copper-based conductive material layer including the conductive base layer and the electroplated copper layer may be formed.

A chemical mechanical polishing process may be performed to remove portions of the copper-based conductive material layer that overlie the horizontal plane including the top surface of the polymer dielectric layer 126. Each remaining portion of the copper-based conductive material layer filing a respective one of the pad cavities 127 constitutes a memory-die copper bonding pad 128. The memory-die copper bonding pads 128 are composed primarily of copper, and may include copper at an atomic percentage of at least 90%, such as at least 95% and/or at least 98%.

The memory-die copper bonding pads 128 may comprise central memory-die copper bonding pads 128C that contact a first subset of the aluminum pad structures 152 and are electrically connected to a respective one of the through-stack via structures 486, and peripheral memory-die copper bonding pads 128P that contact a second subset of the aluminum pad structures 152 and are electrically connected to the peripheral connection via structures 186. In one embodiment, each memory-die copper bonding pad 128 may comprise a respective sidewall that vertically extends straight from a top surface of an aluminum pad structure 152 to a top surface of the polymer dielectric layer 126. Each memory-die copper bonding pad 128 may comprise a respective proximal sidewall segment in contact with the polymer dielectric layer 126 and a respective distal sidewall segment in contact with the at least one second memory-die proximal inorganic dielectric layer 124.

As used herein, a “proximal” element of a memory die 900 refers to an element that is proximal to a bonding interface to be formed on the polymer dielectric layer 126, which is the top surface of the polymer dielectric layer 126. As used herein, a “distal” element of a memory die 900 refers to an element that is distal from the bonding interface to be formed on the polymer dielectric layer 126, which is the top surface of the polymer dielectric layer 126. In one embodiment, for each memory-die copper bonding pad 128, the proximal sidewall segment may be vertically coincident with the distal sidewall segment. In one embodiment, for each memory-die copper bonding pad 128, the entirety of the proximal sidewall segment may be located entirely within a set of at least one vertical plane containing the distal sidewall segment. A plurality of unit bonded assemblies 1000 may be formed.

In an alternative embodiment, shown in FIGS. 26C and 26D, the memory-die copper bonding pad 128 may be formed prior to forming the first polymer dielectric layer 126 instead of by the damascene process shown in FIGS. 25 and 26A. Referring to FIG. 26C, the memory-die copper bonding pads 128 may be formed on the aluminum pad structures 152 by depositing one or more layers of the memory-die copper bonding pads 128 (e.g., metallic barrier layer, copper seed layer and plated copper layer), and then patterning the layers by photolithography and etching. Referring to FIG. 26D, the memory-die proximal inorganic dielectric layer 124 and first polymer dielectric 126 are deposited over the memory-die copper bonding pads 128. The memory-die proximal inorganic dielectric layer 124 and first polymer dielectric 126 are then planarized by CMP to expose the top surfaces of the memory-die copper bonding pads 128, as shown in FIGS. 26A and 26B.

Referring to FIG. 27, a composite bonded assembly that is free of any solder material can be formed by bonding a pair of unit bonded assemblies 1000 such that a first memory die 900 in a first unit bonded assembly 1000 is bonded to a second memory die 900 in a second unit bonded assembly via hybrid bonding.

In summary, the first memory die 900 includes a first alternating stack (32, 46) of first insulating layers 32 and first electrically conductive layers 46, first memory stack structures 55 vertically extending through the first alternating stack (32, 46), first metal interconnect structures (such as first proximal memory-die metal interconnect structures (122, 152)) embedded within first memory-die inorganic dielectric layers (106, 124), and first memory-die copper bonding pads 128 contacting a respective one of the first metal interconnect structures (such as first proximal memory-die metal interconnect structures (122, 152)) and embedded within a first polymer dielectric layer 126. The first memory die 900 may be provided in a first unit bonded assembly 1000, in which a first memory-controller die 700 is bonded to the first memory die 900 via a first hybrid bonding, which includes a copper-to-copper bonding between controller-die front bonding structures 798 and memory-die front bonding structures 198 and an inorganic dielectric-to-dielectric bonding between controller-die front dielectric material layers 760 and memory-die front dielectric material layers 160. In this case, the first memory-controller die 700 comprises a first memory controller circuit configured to control operation of the first memory stack structures 55 and first electrically conductive layers (e.g., word lines and select gate electrodes) 46, and the first memory-controller die 700 can be bonded to the first memory die 900 prior to bonding the first memory die 900 to the second memory die 900.

In one embodiment, the first memory-controller die 700 comprises a first controller-die semiconductor substrate (such as a semiconductor substrate 709) on which the first memory controller circuit 720 is located. In one embodiment, the first memory die 900 comprises first additional memory-die copper bonding pads 198 embedded within first additional memory-die inorganic dielectric layers (e.g., the memory-die front dielectric material layers 160) that are more distal from a bonding interface between the first memory die 900 and the second memory die 900 than the first alternating stack (32, 46) is from the bonding interface between the first memory die 900 and the second memory die 900. In one embodiment, the first memory-controller die 700 comprises first controller-die copper bonding pads (e.g., the controller-die front bonding structures 798) embedded within first controller-die inorganic dielectric layers (e.g., the controller-die front dielectric material layers 760). In one embodiment, the first memory-controller die 700 is bonded to the first memory die 900 by bonding the first controller-die copper bonding pads 798 to the first additional memory-die copper bonding pads 198

Further, a second memory die 900 can be provided, which includes a second alternating stack (32, 46) of second insulating layers 32 and second electrically conductive layers 46, second memory stack structures 55 vertically extending through the second alternating stack (32, 46), second metal interconnect structures (such as second proximal memory-die metal interconnect structures (122, 152)) embedded within second memory-die inorganic dielectric layers (106, 124), and second memory-die copper bonding pads 128 contacting a respective one of the second metal interconnect structures (such as second proximal memory-die metal interconnect structures (122, 152)) and embedded within a second polymer dielectric layer 126. The second memory die 900 may be provided in a second unit bonded assembly 1000, in which a second memory-controller die 700 is bonded to the second memory die 900 via a second hybrid bonding, which includes a copper-to-copper bonding between controller-die front bonding structures 798 and memory-die front bonding structures 198 and an inorganic dielectric-to-dielectric bonding between controller-die front dielectric material layers 760 and memory-die front dielectric material layers 160. In this case, the second memory-controller die 700 comprises a second memory controller circuit configured to control operation of the second memory stack structures 55, and the second memory-controller die 700 can be bonded to the second memory die 900 prior to attaching the first memory die 900 to the second memory die 900.

In one embodiment, the second memory-controller die 700 comprises a second controller-die semiconductor substrate (such as a semiconductor substrate 709) on which the second memory controller circuit 720 is located. In one embodiment, the second memory die 900 comprises second additional memory-die copper bonding pads 198 embedded within second additional memory-die inorganic dielectric layers (e.g., the memory-die front dielectric material layers 160) that are more distal from a bonding interface between the first memory die 900 and the second memory die 900 than the second alternating stack (32, 46) is from the bonding interface between the first memory die 900 and the second memory die 900. In one embodiment, the second memory-controller die 700 comprises second controller-die copper bonding pads (e.g., the controller-die front bonding structures 798) embedded within second controller-die inorganic dielectric layers (e.g., the controller-die front dielectric material layers 760). In one embodiment, the second memory-controller die 700 is bonded to the second memory die 900 by bonding the second controller-die copper bonding pads (e.g., the controller-die front bonding structures 798) to the second additional memory-die copper bonding pads (e.g., the memory-die front dielectric material layers 160).

According to an aspect of the present disclosure, the first memory die 900 can be attached to the second memory die 900 by bonding the first memory-die copper bonding pads 128 to the second memory-die copper bonding pads 128 by a first copper-to-copper bonding. In addition, the first polymer dielectric layer 126 can be bonded to the second polymer dielectric layer 126 by a polymer-to-polymer bonding while attaching the first memory die 900 to the second memory die 900. The polymer-to-polymer bonding between the first polymer dielectric layer 126 and the second polymer dielectric layer 126 and the copper-to-copper bonding between the first memory-die copper bonding pads 128 to the second memory-die copper bonding pads 128 can be performed simultaneously by performing an anneal process at an elevated temperature in a range from 200 degrees Celsius to 350 degrees Celsius, although lower and higher temperatures may also be employed. During the anneal process, the first polymer dielectric layer 126 and the second polymer dielectric layer 126 are bonded to each other to provide the polymer-to-polymer bonding between the first memory die 900 and the second memory die 900.

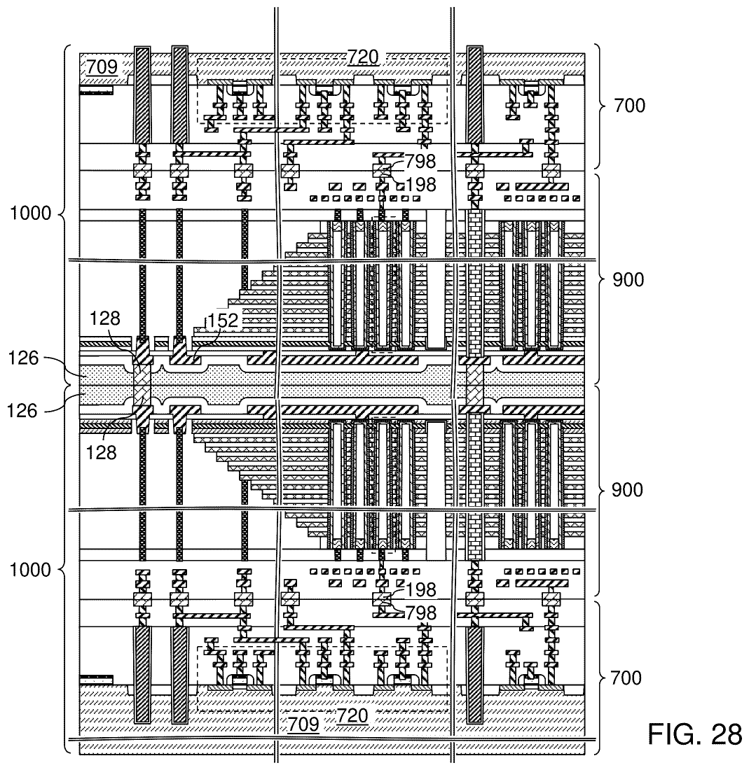

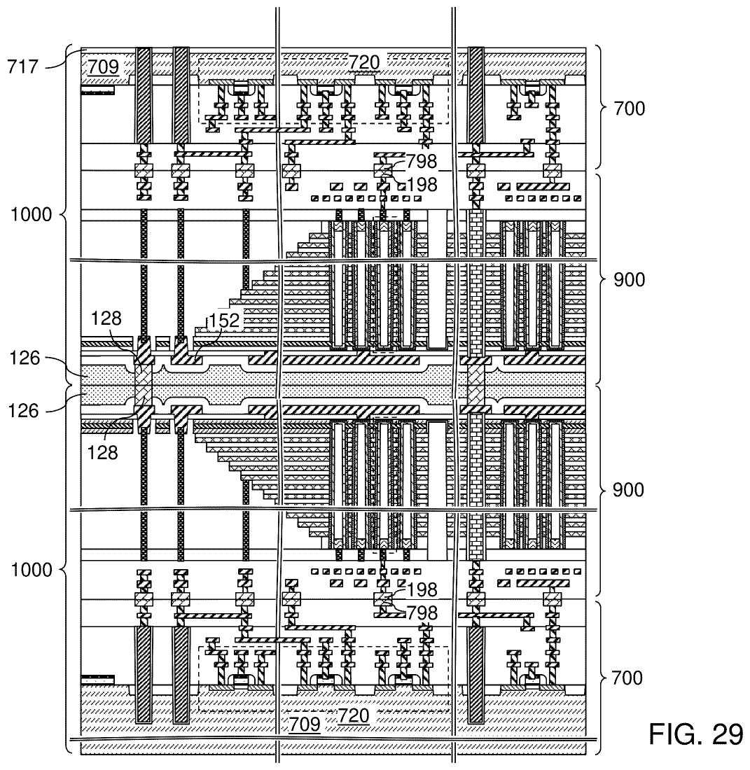

Referring to FIG. 28, the backside portion of the first controller-side semiconductor substrate (i.e., the semiconductor substrate 709) of the first memory-controller die 700 may be thinned, for example, by grinding, polishing, at least one anisotropic etch process, and/or at least one isotropic etch process. Bottom surfaces of the dielectric spacers 714 and/or the through-substrate via (TSV) structures 716 of the first memory-controller die 700 may be physically exposed.

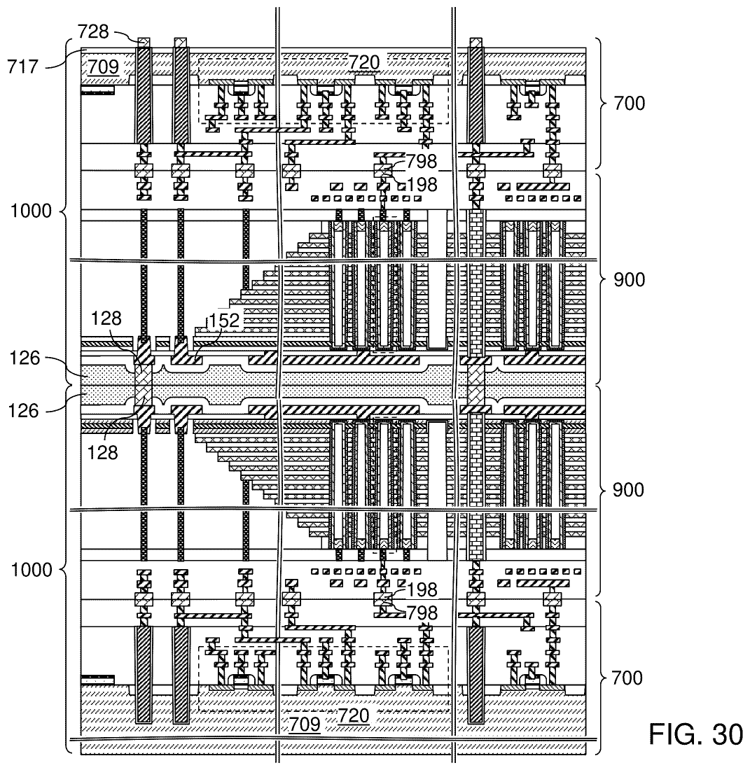

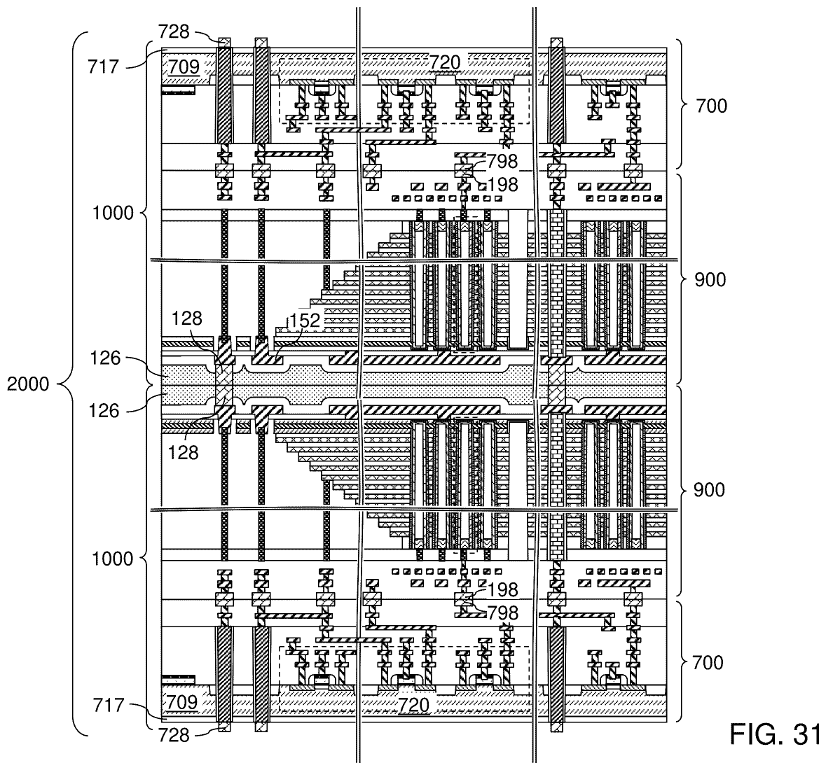

Referring to FIG. 29, an inorganic dielectric material, such as silicon oxide, silicon nitride, silicon oxynitride, silicon carbonitride or a dielectric metal oxide, may be deposited, and may be optionally planarized, over the physically exposed backside surface of the first controller-side semiconductor substrate of the first memory-controller die 700 to form a first controller-die backside dielectric layer 717.

Referring to FIG. 30, first controller-die backside bonding structures 728 can be formed on the backside end surfaces of the TSV structures 716 of the first memory-controller die 700. The first controller-die backside bonding structures 728 may comprise any type of bonding structures known in the art. In one embodiment, the first controller-die backside bonding structures 728 may comprise micro-bump bonding structures, such chip connection (C2) bump structures consisting essentially of copper and configured for a solder-mediated bonding, or solder micro-bumps or balls which are formed on memory redistribution layers (RDLs) and/or under bump metallization (UBM). In another embodiment, the first controller-die backside bonding structures 728 may comprise copper bonding pads.

Referring to FIG. 31, the processing steps described with reference to FIG. 28-30 may be performed on the second memory-controller die 700 to thin the backside portion of the first controller-side semiconductor substrate (i.e., the semiconductor substrate 709) of the second memory-controller die 700, to form a second controller-die backside dielectric layer 717 on the physically exposed backside surface of the first controller-side semiconductor substrate, and to form second controller-die backside bonding structures 728 can be formed on the backside end surfaces of the TSV structures 716 of the second memory-controller die 700. The second controller-die backside bonding structures 728 may comprise the same composition as the first controller-die backside bonding structures 728.

In summary, a semiconductor structure comprising a composite bonded assembly, such as the high bandwidth flash memory assembly 2000 illustrated in FIG. 31, is formed. The composite bonded assembly comprises: a first memory die 900 including a first alternating stack (32, 46) of first insulating layers 32 and first electrically conductive layers 46, first memory stack structures 55 vertically extending through the first alternating stack (32, 46), first metal interconnect structures (such as first proximal memory-die metal interconnect structures (122, 152)) embedded within first memory-die inorganic dielectric layers (106, 124), and first memory-die copper bonding pads 128 electrically contacting a respective one of the first metal interconnect structures (such as first proximal memory-die metal interconnect structures (122, 152)) and embedded within a first polymer dielectric layer 126; and a second memory die 900 including a second alternating stack (32, 46) of second insulating layers 32 and second electrically conductive layers 46, second memory stack structures 55 vertically extending through the second alternating stack (32, 46), second metal interconnect structures (such as second proximal memory-die metal interconnect structures (122, 152)) embedded within second memory-die inorganic dielectric layers (106, 124), and second memory-die copper bonding pads 128 electrically contacting a respective one of the second metal interconnect structures (such as second proximal memory-die metal interconnect structures (122, 152)) and embedded within a second polymer dielectric layer 126, wherein the first memory-die copper bonding pads 128 are bonded to the second memory-die copper bonding pads 128 by a first copper-to-copper bonding.

In one embodiment, the first polymer dielectric layer 126 is bonded to the second polymer dielectric layer 126 by a polymer-to-polymer bonding. In one embodiment, each of the first memory-die copper bonding pads 128 comprises a first proximal sidewall segment in contact with the first polymer dielectric layer 126 and a first distal sidewall segment in contact with one of the first memory-die inorganic dielectric layers (106, 124). In one embodiment, for each of the first memory-die copper bonding pads 128, the first proximal sidewall segment is vertically coincident with the first distal sidewall segment. In one embodiment, each of the second memory-die copper bonding pads 128 comprises a second proximal sidewall segment in contact with the second polymer dielectric layer 126 and a second distal sidewall segment in contact with one of the second memory-die inorganic dielectric layers (106, 124).

In one embodiment, the first polymer dielectric layer 126 and the second polymer dielectric layer 126 comprise a polymer material selected from polyimide, benzocyclobutene (BCB), or an epoxy-based resin. In one embodiment, the first metal interconnect structures (such as first proximal memory-die metal interconnect structures (122, 152)) comprise first aluminum pad structures 152 in direct contact with the first memory-die copper bonding pads 128. In one embodiment, the first metal interconnect structures (such as first proximal memory-die metal interconnect structures (122, 152)) are vertically spaced from the first polymer dielectric layer 126 by one of the first memory-die inorganic dielectric layers (106, 124) that is most proximal to a bonding interface between the first memory die 900 and the second memory die 900. In one embodiment, the first memory die 900 comprises a first source layer 110 interposed between the first alternating stack (32, 46) and the first memory-die inorganic dielectric layers (106, 124); and a subset of the first aluminum pad structures 152 comprises a respective via portion that vertically extends through a respective opening through the first source layer 110.

In one embodiment, the bonded assembly comprises a first memory-controller die 700, wherein the first memory-controller die 700 is bonded to the first memory die 900 and comprises a first memory controller circuit 720 configured to control operation of the first memory stack structures 55. In one embodiment, the first memory die 900 comprises first additional memory-die copper bonding pads (as embodied as memory-die front dielectric material layers 160) embedded within first additional memory-die inorganic dielectric layers (as embodied as memory-die front dielectric material layers 160) that are more distal from a bonding interface between the first memory die 900 and the second memory die 900 than the first alternating stack (32, 46) is from the bonding interface; and the first memory-controller die 700 comprises first controller-die copper bonding pads (as embodied as controller-die front bonding structures 798) embedded within first controller-die inorganic dielectric layers (as embodied as controller-die front dielectric material layers 760) and bonded to the first additional memory-die copper bonding pads (as embodied as memory-die front dielectric material layers 160).

In one embodiment, the bonded assembly comprises a second memory-controller die 700, wherein the second memory-controller die 700 is bonded to the second memory die 900 and comprises a second memory controller circuit 720 configured to control operation of the second memory stack structures 55. In one embodiment, the first memory die 900 is bonded to the first memory-controller die 700 by a combination of a second copper-to-copper bonding and a first oxide-to-oxide bonding; and the second memory die 900 is bonded to the second memory-controller die 700 by a combination of a third copper-to-copper bonding and a second oxide-to-oxide bonding.

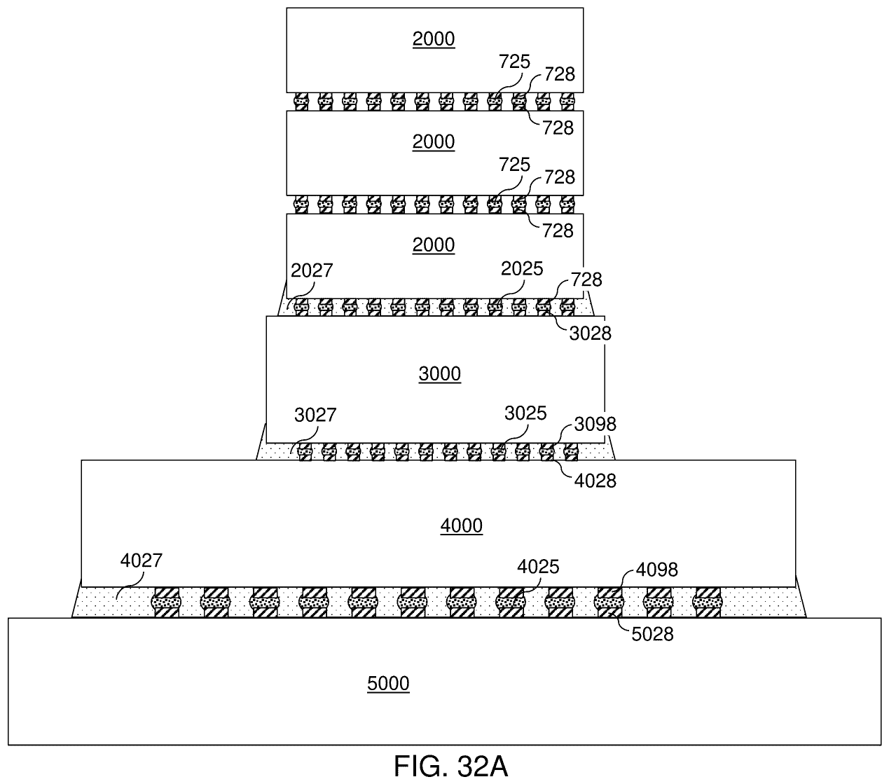

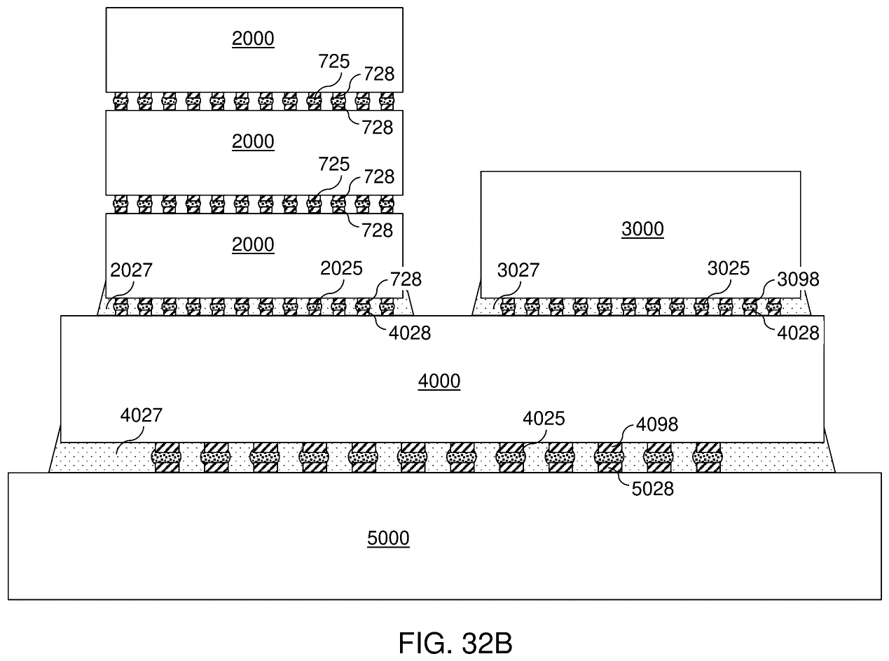

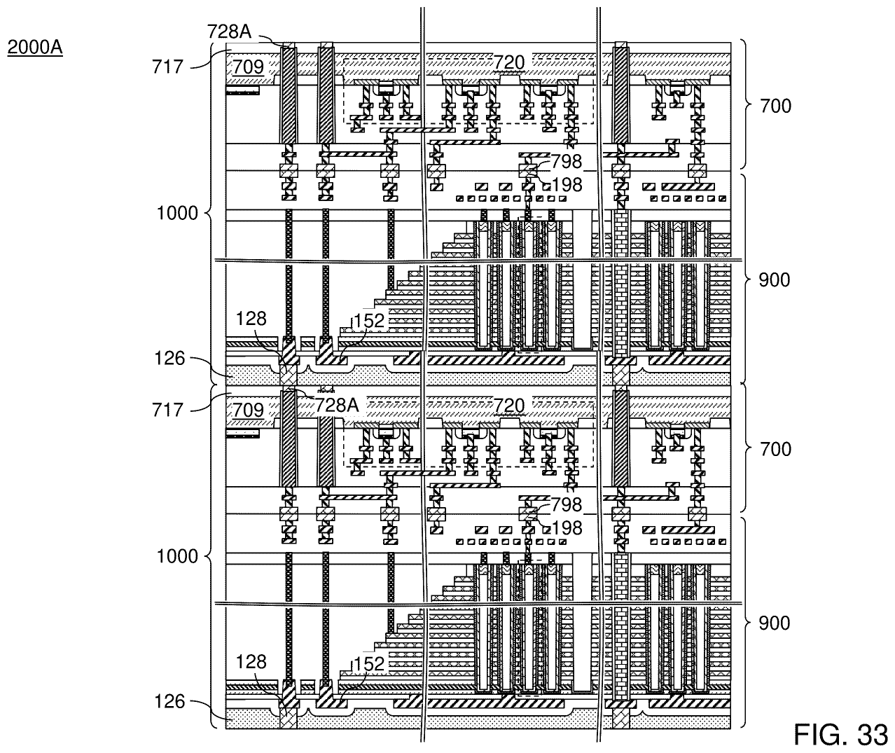

The structure containing plural high bandwidth flash memory assemblies 2000 illustrated in FIG. 31 may be diced to form separate chips each comprising at least one assembly. The diced chips are then bonded to each other and to a semiconductor package structure (3000, 4000, 5000) comprising package-side bump structures (3028, 4028) in various configurations such as the configurations illustrated in FIGS. 32A and 32B. FIG. 32A is a vertical cross-sectional view of a first exemplary structure including multiple instances of the second exemplary bonded assembly according to an embodiment of the present disclosure. FIG. 32B is a vertical cross-sectional view of a second exemplary structure including multiple instances of the second exemplary bonded assembly according to an embodiment of the present disclosure.

The first exemplary structure illustrated in FIG. 32A includes a vertical stack of multiple high bandwidth flash memory assemblies 2000 that are stacked along a vertical direction, an optional system-level logic die 3000, an optional interposer 4000, and a packaging substrate 5000 according to an embodiment of the present disclosure. The multiple instances of a high bandwidth flash memory assembly 2000 are vertically stacked, and are bonded among one another trough arrays of inter-memory solder material portions 725. Each inter-memory solder material portions 725 may be bonded to a respective pair of controller-die backside bonding structures 728. The vertical stack of multiple high bandwidth flash memory assemblies 2000 may be bonded to the system-level logic die 3000.

The second exemplary structure illustrated in FIG. 32B includes multiple instances of a high bandwidth flash memory assembly 2000 that are stacked along a vertical direction, the optional system-level logic die 3000, the optional interposer 4000, and the packaging substrate 5000 according to an embodiment of the present disclosure. The vertical stack of multiple high bandwidth flash memory assemblies 2000 may be bonded to the interposer 4000.

The system-level logic die 3000, if present, controls the operation of the memory-controller dies 700 in each bonded assembly 1000 of the high bandwidth flash memory assembly 2000. The system-level logic die 3000 may comprise at least one of a central processing unit (CPU), a graphics processing unit (GPU), neural processing unit (NPU), and a digital signal processor (DSP). A bottommost instance of the high bandwidth flash memory assembly 2000 may be bonded to the system-level logic die 3000 or to the interposer 4000 through an array of solder material portions 2025. In one embodiment, the controller-die backside bonding structures 728 of the bottommost instance of the high bandwidth flash memory assembly 2000 may be bonded to top logic-die bump structures 3028 through an array of solder material portions 2025 as illustrated in FIG. 32A. Alternatively, the controller-die backside bonding structures 728 of the bottommost instance of the high bandwidth flash memory assembly 2000 may be bonded to top interposer bump structures 4028 through an array of solder material portions 2025 as illustrated in FIG. 32B. An underfill material portion 2027 may be applied around the array of solder material portions 2025.

The interposer 4000 may comprise any type of interposer known in the art. For example, the packaging substrate 5000 may comprise a ceramic interposer or an organic interposer. The system-level logic die 3000 may be bonded to the interposer 4000 through an array of solder material portions 3025. For example, the bottom logic-die bump structures 3098 of the system-level logic die 3000 may be bonded to top interposer bump structures 4028 of the interposer 4000 through the array of solder material portions 3025. An underfill material portion 3027 may be applied around the array of solder material portions 3025.

The packaging substrate 5000 may comprise any type of packaging substrate known in the art. For example, the packaging substrate 5000 may comprise a cored packaging substrate, a non-cored packaging substrate, etc. The interposer 4000 may be bonded to the interposer 4000 through an array of solder material portions 4025. For example, the bottom interposer bump structures 4098 of the interposer 4000 may be bonded to top substrate bump structures 5028 of the packaging substrate 5000 through the array of solder material portions 4025. An underfill material portion 4027 may be applied around the array of solder material portions 4025.

For each bonded assembly which may comprise a high bandwidth flash memory assembly 2000, a semiconductor package structure (2000, 3000, 4000, 5000) comprising package-side bump structures (3028, 4028) may be provided. The first memory-controller die 700 of the high bandwidth flash memory assembly 2000 comprises first controller-die backside bonding structures 728 located on an opposite side of the first controller-die copper bonding pads (as embodied as controller-die front bonding structures 798). The package-side bump structures (3028, 4028) are bonded to the first controller-die backside bonding structures 728 through an array of solder material portions 2025. In one embodiment, the semiconductor package structure (2000, 3000, 4000, 5000) comprises: an additional bonded assembly (e.g., an additional high bandwidth flash memory assembly 2000) that comprises a third memory die 900 and a fourth memory die 900 that are bonded to each other through hybrid bonding; or a processor die (as embodied as a system-level logic die 3000) that comprises at least one of a central processing unit (CPU), a graphics processing unit (GPU), neural processing unit (NPU), and a digital signal processor (DSP).

The composite bonded assembly 2000 of FIG. 31 comprises a memory die pair (mDiP) assembly which includes two memory dies 900 and two memory-controller dies 700. The mDiP functions as a chip which is then bonded to other mDiP chips and to the optional system-level logic die 3000, the optional interposer 4000, and the packaging substrate 5000, by various bonding structures, such as by micro-bumps, as shown in FIGS. 32A and 32B.

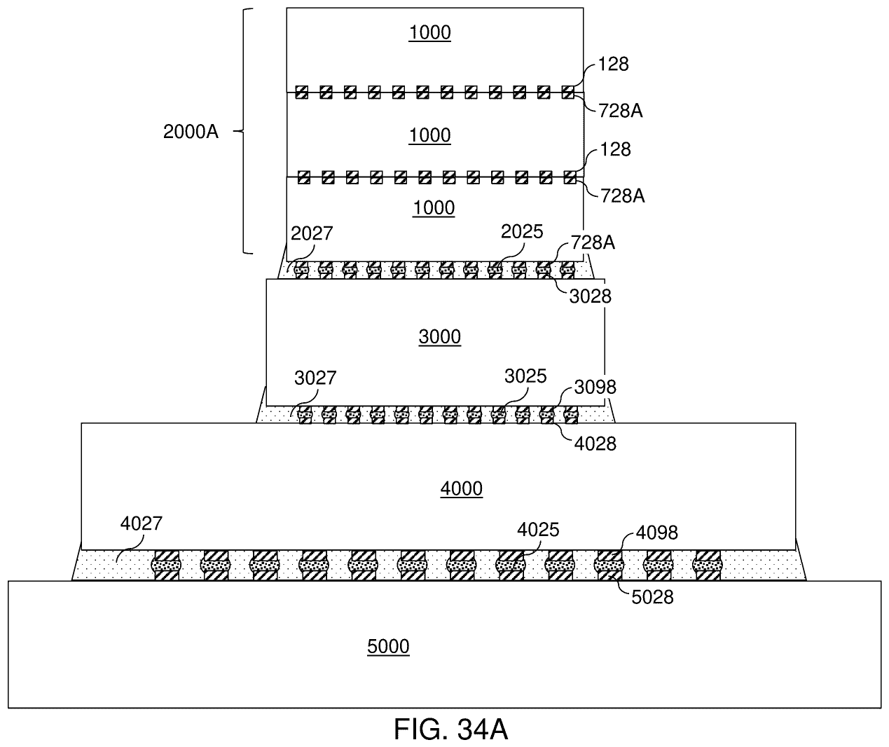

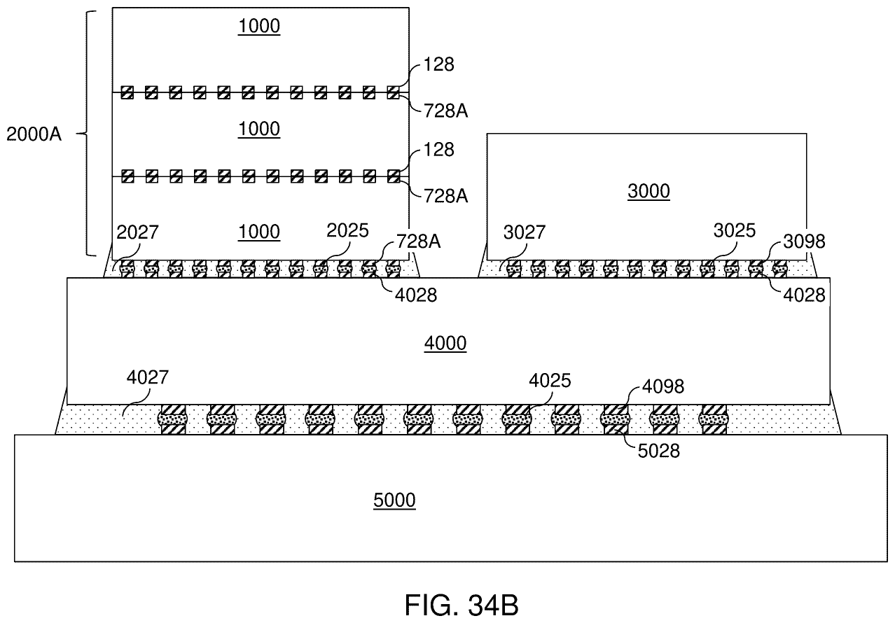

In an alternative embodiment illustrated in FIG. 33, the unit bonded assembly 1000 functions as a chip which is then bonded to other chips unit bonded assemblies 1000 using copper bonding pads 728A to form an alternative composite bonded assembly 2000A. The structure containing plural unit bonded assemblies 1000 illustrated in FIG. 33 may be diced to form separate chips each comprising at least one assembly 1000. The diced chips are then bonded to each other to form the composite bonded assembly 2000A, and to a semiconductor package structure (3000, 4000, 5000) comprising package-side bump structures (3028, 4028) in various configurations such as the configurations illustrated in FIGS. 34A and 34B.

As shown in FIG. 33, the polymer-based hybrid bonding in this alternative embodiment includes cooper-to-copper bonding between opposing the copper bonding pads (128, 728A), and polymer dielectric layer 126 to inorganic backside dielectric layer 717 bonding (i.e., polymer-to-inorganic dielectric bonding). Thus, in this embodiment, the second memory die 900 is bonded to the first memory-controller die 700 by hybrid bonding, in which first controller-die backside bonding structures comprising copper bonding pads 728A embedded in a the first controller-die backside inorganic dielectric layer 717 are bonded to the second memory-die copper bonding pads 128 by copper-to-copper bonding, and the second polymer dielectric layer 126 is bonded to the first controller-die backside inorganic dielectric layer 717 by a polymer-to-inorganic dielectric bonding.

The alternative composite bonded assembly 2000A (or a single chip comprising a unit bonded assembly 1000) is then bonded to the optional system-level logic die 3000, the optional interposer 4000, and the packaging substrate 5000, using any suitable bonding methods, such as micro-bump bonding, as shown in FIGS. 34A and 34B. This reduces the height of the structure and increases the density of the memory devices because copper bonding pads may have a smaller lateral width than micro-bumps.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure comprising a bonded assembly, wherein the bonded assembly comprises:
a first memory die including a first alternating stack of first insulating layers and first electrically conductive layers, first memory stack structures vertically extending through the first alternating stack, first metal interconnect structures embedded within first memory-die inorganic dielectric layers, and first memory-die copper bonding pads contacting a respective one of the first metal interconnect structures and embedded within a first polymer dielectric layer; and
a second memory die including a second alternating stack of second insulating layers and second electrically conductive layers, second memory stack structures vertically extending through the second alternating stack, second metal interconnect structures embedded within second memory-die inorganic dielectric layers, and second memory-die copper bonding pads contacting a respective one of the second metal interconnect structures and embedded within a second polymer dielectric layer.

2. The semiconductor structure of claim 1, wherein:
the first memory-die copper bonding pads are bonded to the second memory-die copper bonding pads by a first copper-to-copper bonding; and
the first polymer dielectric layer is bonded to the second polymer dielectric layer by a polymer-to-polymer bonding.

3. The semiconductor structure of claim 2, wherein:
each of the first memory-die copper bonding pads comprises a first proximal sidewall segment in contact with the first polymer dielectric layer and a first distal sidewall segment in contact with one of the first memory-die inorganic dielectric layers;
for each of the first memory-die copper bonding pads, the first proximal sidewall segment is vertically coincident with the first distal sidewall segment; and
each of the second memory-die copper bonding pads comprises a second proximal sidewall segment in contact with the second polymer dielectric layer and a second distal sidewall segment in contact with one of the second memory-die inorganic dielectric layers.

4. The semiconductor structure of claim 1, wherein the first polymer dielectric layer and the second polymer dielectric layer comprise a polymer material selected from polyimide, benzocyclobutene (BCB), and an epoxy-based resin.

5. The semiconductor structure of claim 1, wherein the first metal interconnect structures comprise first aluminum pad structures in direct contact with the first memory-die copper bonding pads.

6. The semiconductor structure of claim 5, wherein the first metal interconnect structures are vertically spaced from the first polymer dielectric layer by one of the first memory-die inorganic dielectric layers that is most proximal to a bonding interface between the first memory die and the second memory die.

7. The semiconductor structure of claim 5, wherein:
the first memory die comprises a first source layer interposed between the first alternating stack and the first memory-die inorganic dielectric layers; and
a subset of the first aluminum pad structures comprises a respective via portion that vertically extends through a respective opening through the first source layer.

8. The semiconductor structure of claim 1, wherein the bonded assembly further comprises a first memory-controller die, wherein the first memory-controller die is bonded to the first memory die and comprises a first memory controller circuit configured to control operation of the first memory stack structures.

9. The semiconductor structure of claim 8, wherein:
the first memory die comprises first additional memory-die copper bonding pads embedded within first additional memory-die inorganic dielectric layers; and
the first memory-controller die comprises first controller-die copper bonding pads embedded within first controller-die inorganic dielectric layers and bonded to the first additional memory-die copper bonding pads.

10. The semiconductor structure of claim 8, wherein:
the first memory-controller die further comprises first controller-die backside bonding structures comprising copper bonding pads embedded in a controller-die backside inorganic dielectric layer;
the second memory-die copper bonding pads are bonded to first controller-die backside bonding structures by copper-to-copper bonding; and
the second polymer dielectric layer is bonded to the controller-die backside inorganic dielectric layer by a polymer-to-inorganic dielectric bonding.

11. The semiconductor structure of claim 8, wherein:
the bonded assembly further comprises a second memory-controller die;
the second memory-controller die is bonded to the second memory die and comprises a second memory controller circuit configured to control operation of the second memory stack structures;
the first memory die is bonded to the first memory-controller die by a combination of a second copper-to-copper bonding and a first oxide-to-oxide bonding; and
the second memory die is bonded to the second memory-controller die by a combination of a third copper-to-copper bonding and a second oxide-to-oxide bonding.

12. The semiconductor structure of claim 11, further comprising a semiconductor package structure comprising package-side bump structures.

13. The semiconductor structure of claim 12, wherein:
the first memory-controller die comprises first controller-die backside bonding structures located on an opposite side of the first controller-die copper bonding pads; and
the package-side bump structures are bonded to the first controller-die backside bonding structures through an array of solder material portions.

14. The semiconductor structure of claim 12, wherein the semiconductor package structure further comprises:
an additional bonded assembly that comprises a third memory die and a fourth memory die that are bonded to each other through hybrid bonding; or
a processor die that comprises at least one of a central processing unit (CPU), a graphics processing unit (GPU), neural processing unit (NPU), and a digital signal processor (DSP).

15. A method of forming a bonded assembly, comprising:
providing a first memory die including a first alternating stack of first insulating layers and first electrically conductive layers, first memory stack structures vertically extending through the first alternating stack, first metal interconnect structures embedded within first memory-die inorganic dielectric layers, and first memory-die copper bonding pads contacting a respective one of the first metal interconnect structures and embedded within a first polymer dielectric layer;
providing a second memory die including a second alternating stack of second insulating layers and second electrically conductive layers, second memory stack structures vertically extending through the second alternating stack, second metal interconnect structures embedded within second memory-die inorganic dielectric layers, and second memory-die copper bonding pads contacting a respective one of the second metal interconnect structures and embedded within a second polymer dielectric layer; and
providing the first memory die and the second memory die into a bonded assembly.

16. The method of claim 15, wherein the first metal interconnect structures comprise first aluminum pad structures, and the method further comprises contacting a probe to at least one of the first aluminum pad structures to electrically test the first memory die prior to forming the first memory-die copper bonding pads.

17. The method of claim 15, wherein the providing the first memory die and the second memory die into a bonded assembly comprises bonding the first memory die to the second memory die by bonding the first memory-die copper bonding pads to the second memory-die copper bonding pads by a first copper-to-copper bonding; and bonding the first polymer dielectric layer to the second polymer dielectric layer by a polymer-to-polymer bonding while attaching the first memory die to the second memory die.

18. The method of claim 15, further comprising:
providing a first memory-controller die that comprises a first memory controller circuit configured to control operation of the first memory stack structures; and
bonding the first memory-controller die to the first memory die prior to the providing the first memory die and the second memory die into a bonded assembly.

19. The method of claim 18, wherein:
the first memory die comprises first additional memory-die copper bonding pads embedded within first additional memory-die inorganic dielectric layers that are more distal from a bonding interface between the first memory die and the second memory die than the first alternating stack is from the bonding interface;
the first memory-controller die comprises first controller-die copper bonding pads embedded within first controller-die inorganic dielectric layers; and
the first memory-controller die is bonded to the first memory die by bonding the first controller-die copper bonding pads to the first additional memory-die copper bonding pads.

20. The method of claim 18, wherein the second memory die is bonded to the first memory-controller die by hybrid bonding.
